(19) United States
(12) Patent Application Publication
(10) Pub. No.: US 2026/0075831 A1
(43) Pub. Date: Mar. 12, 2026

(54) FERROELECTRIC MEMORY DEVICE AND METHOD OF FORMING THE SAME

(71) Applicant: Taiwan Semiconductor Manufacturing Company, Ltd., Hsinchu (TW)

(72) Inventors: Yen-Chieh Huang, Hsinchu (TW); Chun-Chieh Lu, Taipei City (TW); Chih-Yu CHANG, New Taipei City (TW); Huai-Ying HUANG, New Taipei City (TW); Yu-Chuan Shih, Hsinchu City (TW); Hao-Kai Peng, Hsinchu (TW); Yu-Ming Lin, Hsinchu City (TW)

(73) Assignee: Taiwan Semiconductor Manufacturing Company, Ltd., Hsinchu (TW)

(21) Appl. No.: 18/827,812

(22) Filed: Sep. 8, 2024

(51) Int. Cl. H10B 51/20; H01L 29/66; H01L 29/78; H10B 51/10

(52) U.S. Cl. CPC H10B 51/20; H10B 51/10; H10D 30/0415; H10D 30/701

(57) ABSTRACT

A device includes a multi-layer stack, a plurality of channel segments and a ferroelectric layer. The multi-layer stack is disposed on a substrate and includes a plurality of conductive layers and a plurality of dielectric layers stacked alternately. The channel segments are disposed on sidewalls of the conductive layers, separately and respectively. The ferroelectric layer is disposed between the channel segments and the conductive layers, respectively.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography and etching techniques to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A and FIG. 1B illustrate a simplified perspective view and a circuit diagram of a ferroelectric memory device in accordance with some embodiments.

FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14, FIG. 15A, FIG. 15B, FIG. 16A, FIG. 16B, FIG. 17A, FIG. 17B, FIG. 18A, FIG. 18B, FIG. 18C, FIG. 19A, FIG. 19B, FIG. 19C, FIG. 20, FIG. 21A, FIG. 21B, FIG. 22A, FIG. 22B, FIG. 23A, FIG. 23B, FIG. 24A and FIG. 24B illustrate varying views of manufacturing a ferroelectric memory device in accordance with some embodiments.

FIG. 25 illustrates a simplified perspective view a ferroelectric memory device in accordance with some embodiments.

FIG. 26A and FIG. 26B illustrate varying views of a ferroelectric memory device in accordance with some embodiments.

FIG. 27A and FIG. 27B illustrate varying views of a ferroelectric memory device in accordance with some embodiments.

FIG. 28A and FIG. 28B illustrate varying views of a ferroelectric memory device in accordance with some embodiments.

FIG. 29A and FIG. 29B illustrate varying views of a ferroelectric memory device in accordance with some embodiments.

FIG. 30A and FIG. 30B illustrate varying views of a ferroelectric memory device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a memory device such as a 3D memory array. In some embodiments, the 3D memory array is a ferroelectric field effect transistor (FeFET) memory circuit including multiple vertically stacked memory cells. In some embodiments, each memory cell is regarded as a FeFET that includes a word line region acting as a gate electrode, a bit line region acting as a first source/drain electrode, and a source line region acting as a second source/drain electrode, a ferroelectric material as a gate dielectric, and an oxide semiconductor (OS) as a channel region. In some embodiments, each memory cell is regarded as a thin film transistor (TFT).

Embodiments of the disclosure provide a ferroelectric memory device, in which a channel layer is cut into multiple channel segments corresponding to multiple gate electrodes. By such configuration, the cell-to-cell noise interference is prevented, the off current (I_{off}) or leaky current of the device is significantly reduced, and the Iₒₙ/I_{off} ratio is accordingly enhanced.

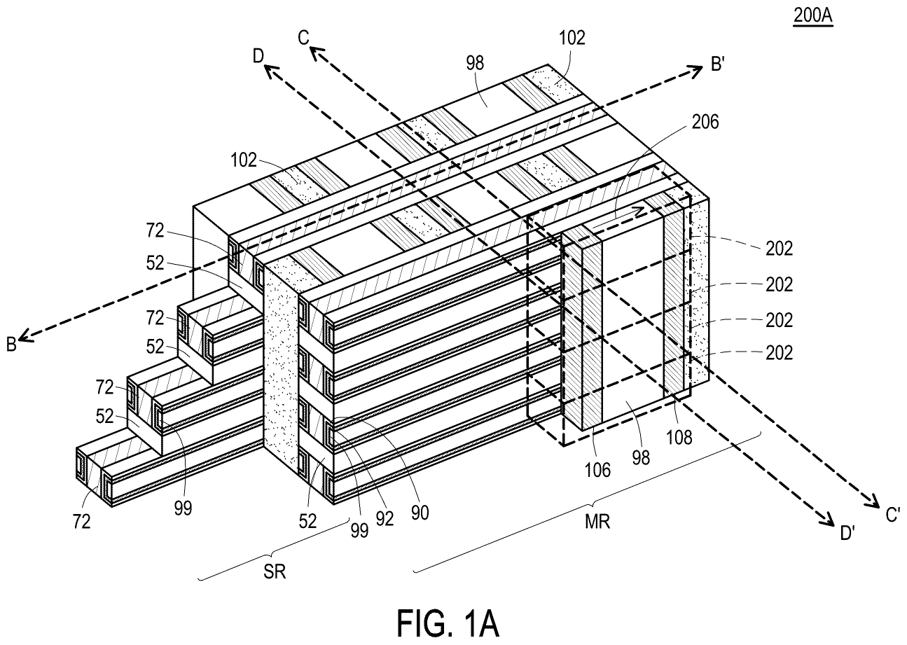

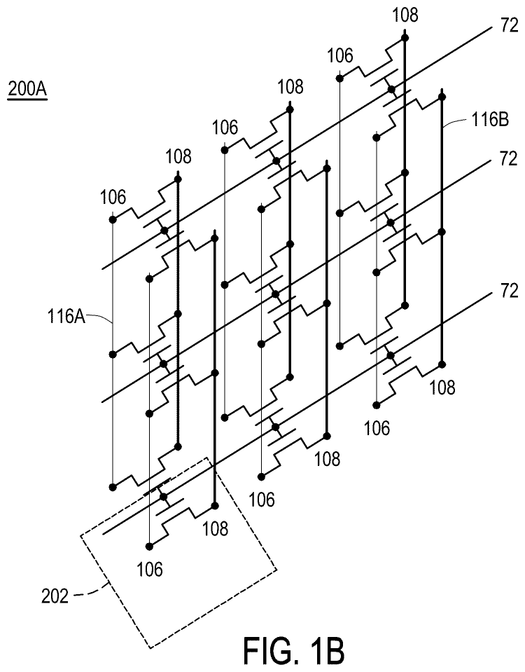

FIG. 1A and FIG. 1B illustrate a ferroelectric memory device according to some embodiments. FIG. 1A illustrates an example of a portion of a simplified ferroelectric memory device 200A in a partial three-dimensional view, and FIG. 1B illustrates a circuit diagram of the ferroelectric memory device 200A. The ferroelectric memory device 200A includes multiple memory cells 202, which may be arranged in a grid of rows and columns. The memory cells 202 may further stacked vertically to provide a three dimensional memory array, thereby increasing device density. The ferroelectric memory device 200A may be disposed in the back end of line (BEOL) of a semiconductor die.

In some embodiments, the ferroelectric memory device 200A is a flash memory array, such as a NOR flash memory array, or the like. In some embodiments, a gate of each memory cell 202 is electrically coupled to a respective word line (e.g., conductive layer 72), a first source/drain region of each memory cell 202 is electrically coupled to a respective bit line (e.g., conductive line 116B), and a second source/drain region of each memory cell 202 is electrically coupled to a respective source line (e.g., conductive line 116A), which electrically couples the second source/drain region to ground. The memory cells 202 in the same horizontal row of the ferroelectric memory device 200A may share a common word line while the memory cells 202 in the same vertical column of the ferroelectric memory device 200A may share a common source line and a common bit line.

The ferroelectric memory device 200A includes multiple vertically stacked conductive layers 72 (e.g., word lines) with dielectric layers 52 disposed between adjacent ones of the conductive layers 72. The conductive layers 72 extend in a direction parallel to a surface of an underlying substrate. The conductive layers 72 may have a staircase configuration, and the stacked conductive layers 72 are illustrated with topmost conductive layers 72 being the shortest and bottommost conductive layers 72 being the longest, as shown in FIG. 1A. Respective lengths of the conductive layers 72 may increase in a direction towards the underlying substrate. In this manner, a portion of each of the conductive layers 72 may be accessible from the ferroelectric memory device 200A, and conductive contacts may be made to exposed portions of the conductive layers 72, respectively.

The ferroelectric memory device 200A further includes conductive pillars 106 (e.g., electrically connected to bit lines) and conductive pillars 108 (e.g., electrically connected to source lines) arranged alternately. The conductive pillars 106 and 108 may each extend in a direction perpendicular to the conductive layers 72. A dielectric material 98 is disposed between and isolates adjacent ones of the conductive pillars 106 and the conductive pillars 108.

Pairs of the conductive pillars 106 and 108 along with an intersecting conductive layer 72 define boundaries of each memory cell 202, and an isolation pillar 102 is disposed between and isolates adjacent pairs of the conductive pillars 106 and 108. In some embodiments, the conductive pillars 108 are electrically coupled to ground. Although FIG. 1A illustrates a particular placement of the conductive pillars 106 relative the conductive pillars 108, it should be appreciated that the placement of the conductive pillars 106 and 108 may be exchanged in other embodiments.

In some embodiments, the ferroelectric memory device 200A may also include an oxide semiconductor (OS) material as a channel layer 92. The channel layer 92 may provide separate channel regions for the memory cells 202. For example, when an appropriate voltage (e.g., higher than a respective threshold voltage (Vth) of a corresponding memory cell 202) is applied through a corresponding conductive layer 72, a region of the channel layer 92 that intersects the conductive layer 72 may allow current to flow from the conductive pillars 106 to the conductive pillars 108 (e.g., in the direction indicated by arrow 206).

In some embodiments, a ferroelectric layer 90 is disposed between the channel layer 92 and each of the conductive layers 72 and the dielectric layers 52, and the ferroelectric layer 90 may serve as a gate dielectric for each memory cell 202. In some embodiments, the ferroelectric layer 90 includes a ferroelectric material, such as a hafnium oxide, hafnium zirconium oxide, silicon-doped hafnium oxide, or the like.

The ferroelectric layer 90 may be polarized in one of two different directions, and the polarization direction may be changed by applying an appropriate voltage differential across the ferroelectric layer 90 and generating an appropriate electric field. The polarization may be relatively localized (e.g., generally contained within each boundaries of the memory cells 202), and a continuous region of the ferroelectric layer 90 may extend across multiple memory cells 202. Depending on a polarization direction of a particular region of the ferroelectric layer 90, a threshold voltage of a corresponding memory cell 202 varies, and a digital value (e.g., 0 or 1) can be stored. For example, when a region of the ferroelectric layer 90 has a first electrical polarization direction, the corresponding memory cell 202 may have a relatively low threshold voltage, and when the region of the ferroelectric layer 90 has a second electrical polarization direction, the corresponding memory cell 202 may have a relatively high threshold voltage. The difference between the two threshold voltages may be referred to as the threshold voltage shift. A larger threshold voltage shift makes it easier (e.g., less error prone) to read the digital value stored in the corresponding memory cell 202.

To perform a write operation on a memory cell 202 in such embodiments, a write voltage is applied across a portion of the ferroelectric layer 90 corresponding to the memory cell 202. In some embodiments, the write voltage is applied, for example, by applying appropriate voltages to a corresponding conductive layer 72 (e.g., the word line) and the corresponding conductive pillars 106/108 (e.g., the bit line/source line). By applying the write voltage across the portion of the ferroelectric layer 90, a polarization direction of the region of the ferroelectric layer 90 can be changed. As a result, the corresponding threshold voltage of the corresponding memory cell 202 can also be switched from a low threshold voltage to a high threshold voltage or vice versa, and a digital value can be stored in the memory cell 202. Because the conductive layers 72 intersect the conductive pillars 106 and 108, individual memory cells 202 may be selected for the write operation.

To perform a read operation on the memory cell 202 in such embodiments, a read voltage (a voltage between the low and high threshold voltages) is applied to the corresponding conductive layer 72 (e.g., the world line). Depending on the polarization direction of the corresponding region of the ferroelectric layer 90, the memory cell 202 may or may not be turned on. As a result, the conductive pillar 106 may or may not be discharged through the conductive pillar 108 (e.g., a source line that is coupled to ground), and the digital value stored in the memory cell 202 can be determined. Because the conductive layers 72 intersect the conductive pillars 106 and 108, individual memory cells 202 may be selected for the read operation.

FIG. 1A further illustrates multiple cross-sections of the ferroelectric memory device 200A that are used in later figures. Cross-section B-B′ is along a longitudinal axis of conductive layers 72 and in a direction, for example, parallel to the direction of current flow of the memory cells 202. Cross-section C-C′ is perpendicular to cross-section B-B′ and extends through the dielectric material 98 and the isolation pillars 102. Cross-section D-D′ is perpendicular to cross-section B-B′ and extends through the dielectric material 98 and the conductive pillars 106. Subsequent figures refer to these cross-sections for clarity.

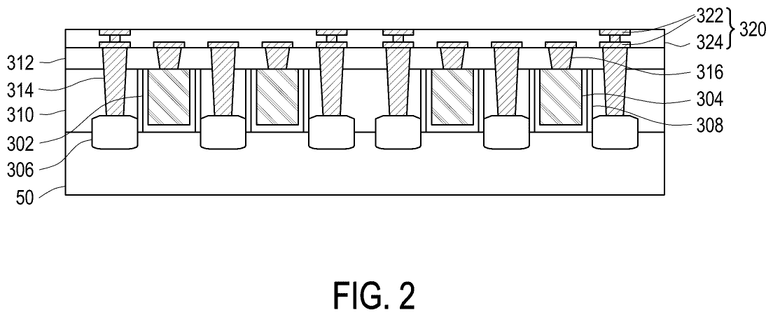

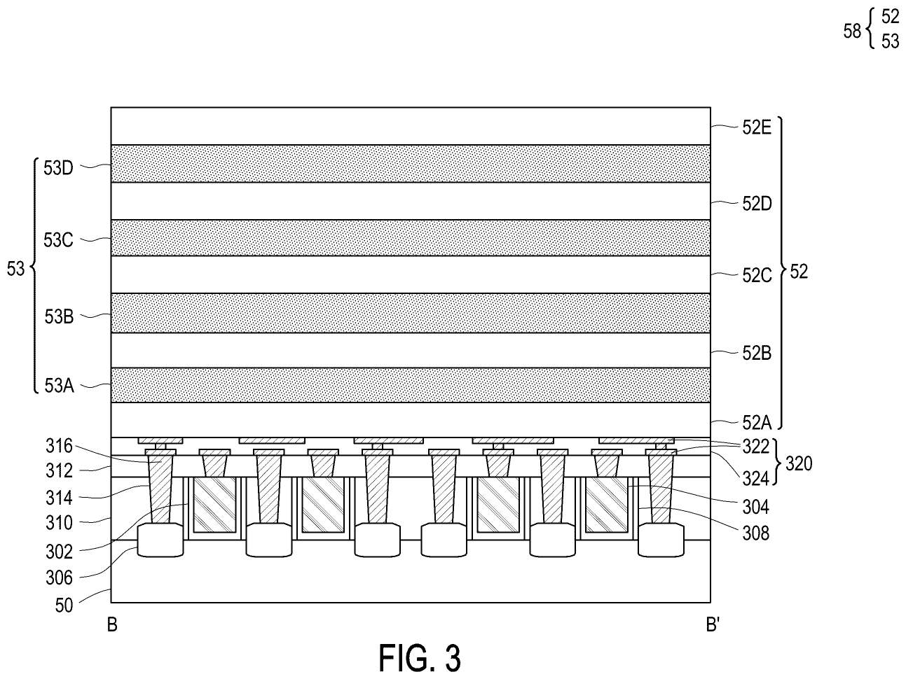

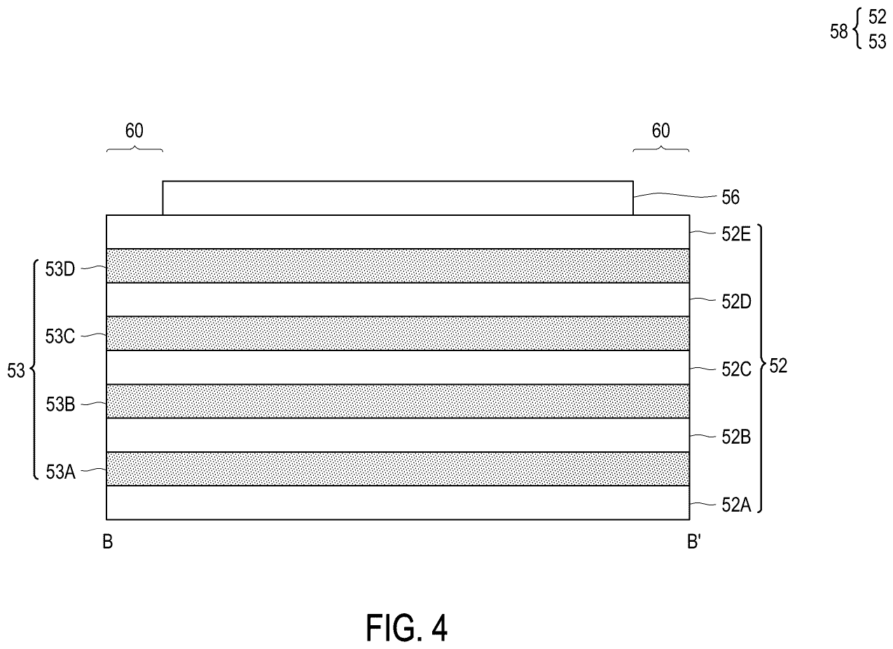

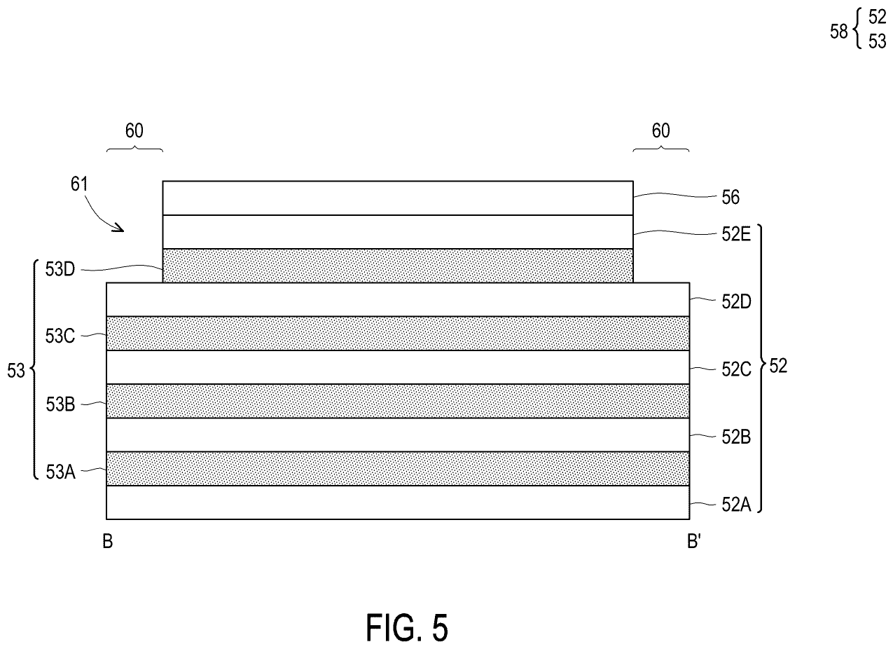

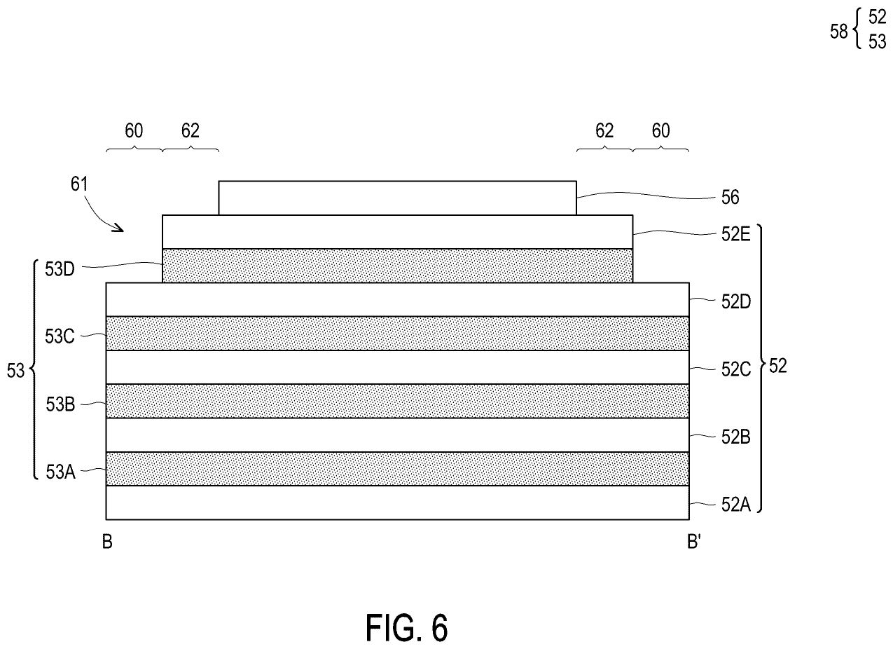

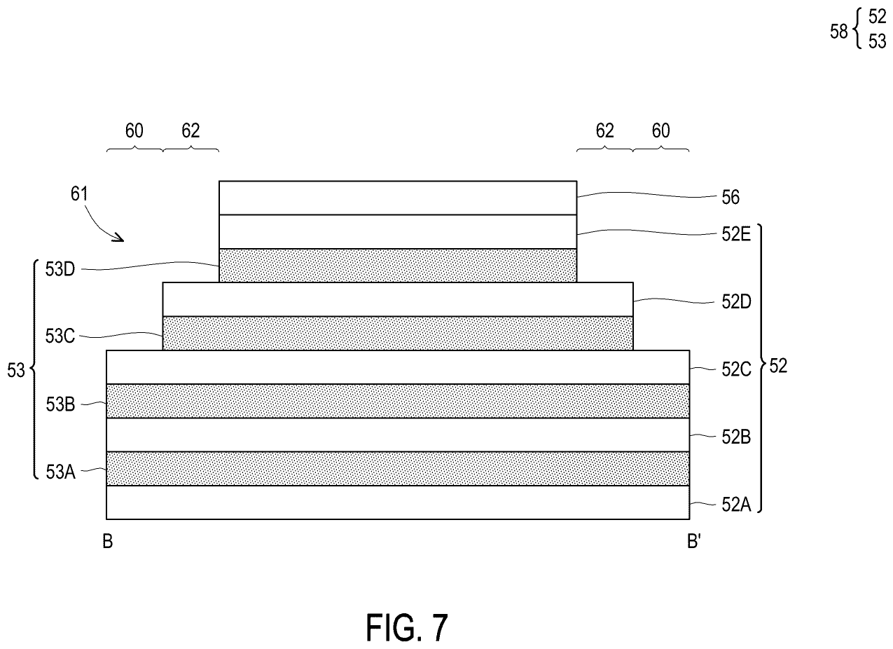

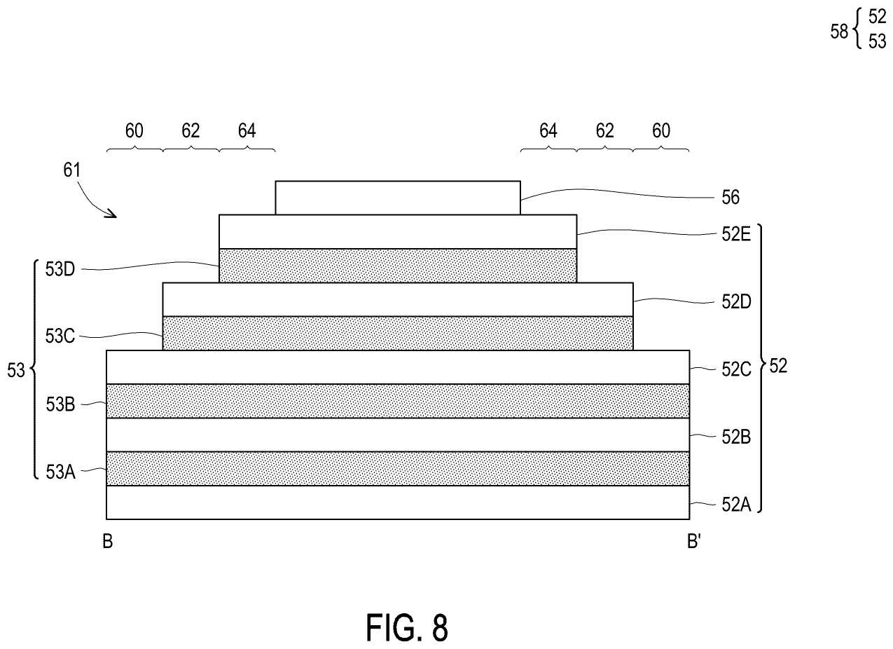

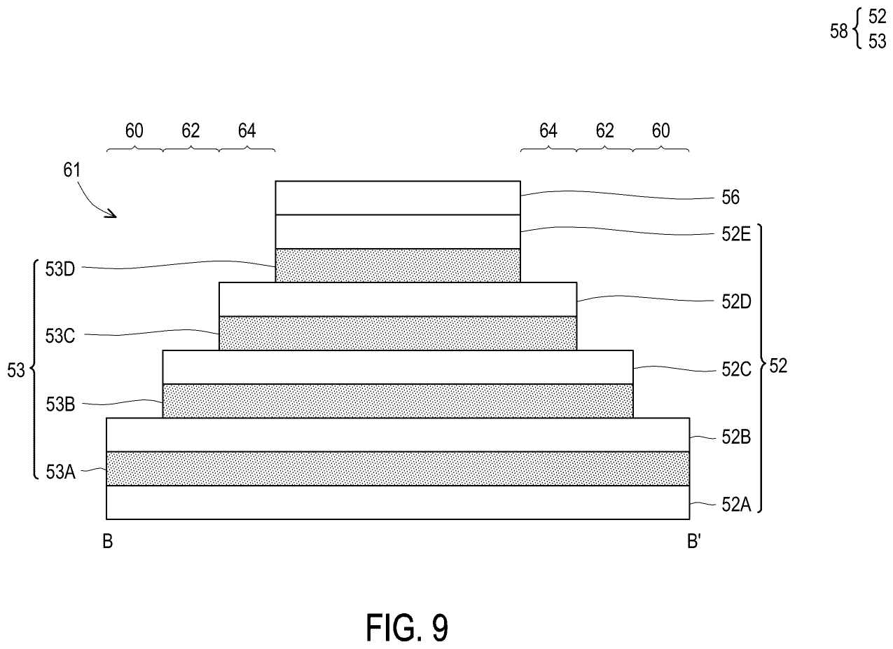

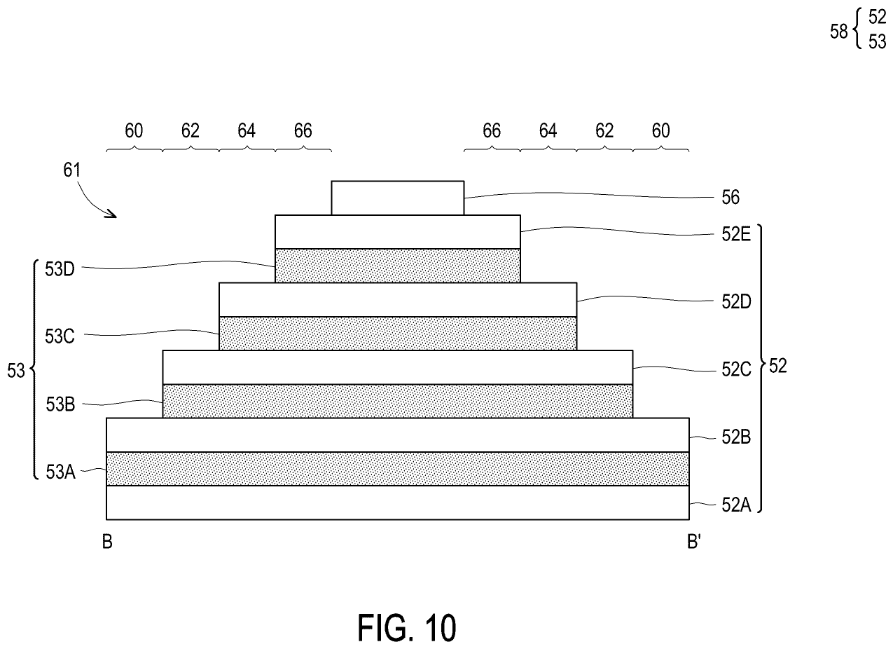

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof.

FIG. 2 further illustrates circuits that may be formed over the substrate 50. The circuits include transistors at a top surface of the substrate 50. The transistors may include gate dielectric layers 302 over top surfaces of the substrate 50 and gate electrodes 304 over the gate dielectric layers 302. Source/drain regions 306 are disposed in the substrate 50 at opposite sides of the gate electrodes 304. Gate spacers 308 are formed along sidewalls of the gate dielectric layers 302 and separate the source/drain regions 306 from the gate electrodes 304 by appropriate lateral distances. The transistors may include fin field effect transistors (FinFETs), nanostructure (e.g., nanosheet, nanowire, gate-all-around, or the like) FETs (nano-FETs), planar FETs, the like, or combinations thereof.

A first inter-layer dielectric (ILD) 310 surrounds and isolates the source/drain regions 306 and the gate electrodes 304, and a second ILD 312 is disposed over the first ILD 310. Source/drain contacts 314 extend through the second ILD 312 and the first ILD 310 and are electrically coupled to the source/drain regions 306, and gate contacts 316 extend through the second ILD 312 and are electrically coupled to the gate electrodes 304. An interconnect structure 320 is disposed over the second ILD 312, the source/drain contacts 314, and the gate contacts 316. The interconnect structure 320 includes conductive features 322 embedded in one or more dielectric layers 324, for example. The interconnect structure 320 may be electrically connected to the gate contacts 316 and the source/drain contacts 314 to form functional circuits, such as logic circuits, memory circuits, sense amplifiers, controllers, input/output circuits, image sensor circuits, the like, or combinations thereof.

In FIG. 3, a multi-layer stack 58 is formed over the structure of FIG. 2. The substrate 50, the transistors, the ILDs, and the interconnect structure 320 may be omitted from subsequent drawings for the purposes of simplicity and clarity. Although the multi-layer stack 58 is illustrated as contacting the dielectric layer 324 of the interconnect structure 320, any number of intermediate layers may be disposed between the substrate 50 and the multi-layer stack 58. For example, one or more conductive features embedded in dielectric layers may be disposed between the interconnect structure 320 and the multi-layer stack 58. In some embodiments, the conductive features may be patterned to provide power, ground, and/or signal lines for the active devices on the substrate 50 and/or the ferroelectric memory device 200A (see FIG. 1A). In some embodiments, one or more interconnect layers including conductive features in dielectric layers may be disposed over the multi-layer stack 58.

In FIG. 3, the multi-layer stack 58 includes alternating layers of sacrificial layers 53A-53D (collectively referred to as sacrificial layers 53) and dielectric layers 52A-52E (collectively referred to as dielectric layers 52). The sacrificial layers 53 may be patterned and replaced in subsequent steps to define conductive layers 72 (e.g., the word lines). Each sacrificial layer 53 may include a dielectric material, such as silicon oxide, silicon nitride, silicon oxynitride, the like, or a combination thereof. Each dielectric layer 52 may include an insulating material, such as silicon oxide, silicon nitride, silicon oxynitride, the like, or a combination thereof. The sacrificial layers 53 and the dielectric layers 52 include different materials with different etching selectivities. In some embodiments, the sacrificial layers 53 include silicon nitride, and the dielectric layers 52 include silicon oxide. Each of the sacrificial layers 53 and the dielectric layers 52 may be formed using, for example, chemical vapor deposition (CVD), atomic layer deposition (ALD), physical vapor deposition (PVD), plasma enhanced CVD (PECVD), or the like.

Although FIG. 3 illustrates a particular number of the sacrificial layers 53 and the dielectric layers 52, other embodiments may include different numbers of the sacrificial layers 53 and the dielectric layers 52. Besides, although the multi-layer stack 58 is illustrated as having dielectric layers as topmost and bottommost layers, the disclosure is not limited thereto. In some embodiments, at least one of the topmost and bottommost layers of the multi-layer stack 58 is a sacrificial layer.

FIG. 4 to FIG. 12 illustrate manufacturing a staircase structure in a staircase region SR of the ferroelectric memory device 200A, in accordance with some embodiments. FIG. 4 to FIG. 12 are illustrated along the cross-section B-B′ in FIG. 1A.

In FIG. 4, a photoresist 56 is formed over the multi-layer stack 58. In some embodiments, the photoresist 56 is formed by a photolithography technique. Patterning the photoresist 56 may expose the multi-layer stack 58 in regions 60, while masking remaining portions of the multi-layer stack 58. For example, a topmost layer of the multi-layer stack 58 (e.g., the dielectric layer 52E) may be exposed in the regions 60.

In FIG. 5, the exposed portions of the multi-layer stack 58 in the regions 60 are etched using the photoresist 56 as a mask. The etching may include a dry etch, a wet etch, or a combination thereof. The etching may remove portions of the dielectric layer 52E and the sacrificial layer 53D in the regions 60 and define openings 61. Because the dielectric layer 52E and the sacrificial layer 53D have different material compositions, etchants used to remove exposed portions of these layers may be different. In some embodiments, the sacrificial layer 53D acts as an etch stop layer while etching the dielectric layer 52E, and the dielectric layer 52D acts as an etch stop layer while etching sacrificial layer 53D. As a result, the portions of the dielectric layer 52E and the sacrificial layer 53D may be selectively removed without removing remaining layers of the multi-layer stack 58, and the openings 61 may be extended to a desired depth. Alternatively, a time-mode etching process may be used to stop the etching of the openings 61 after the openings 61 reach a desired depth. In the resulting structure, the dielectric layer 52D is exposed in the regions 60.

In FIG. 6, the photoresist 56 is trimmed to expose additional portions of the multi-layer stack 58. In some embodiments, the photoresist 56 is trimmed by a lateral etching. As a result of the trimming, a width of the photoresist 56 is reduced and portions the multi-layer stack 58 in the regions 60 and regions 62 may be exposed. For example, top surfaces of the dielectric layer 52D may be exposed in the regions 60, and top surfaces of the dielectric layer 52E may be exposed in the regions 62.

In FIG. 7, portions of the dielectric layer 52E, the sacrificial layer 53D, the dielectric layer 52D, and the sacrificial layer 53C in the regions 60 and the regions 62 are removed by an etching process using the photoresist 56 as a mask. The etching may include a dry etch, a wet etch, or a combination thereof. The etching may extend the openings 61 further into the multi-layer stack 58. Because the sacrificial layers 53D and 53C and the dielectric layers 52E and 52D have different material compositions, etchants used to remove exposed portions of these layers may be different. In some embodiments, portions of the dielectric layers 52E and 52D in the regions 62 and 60 are removed by using the photoresist 56 as a mask and using the underlying sacrificial layers 53D and 53C as etch stop layers. Thereafter, the exposed portions of the sacrificial layers 53D and 53C in the regions 62 and 60 are removed by using the photoresist 56 as a mask and using the underlying dielectric layers 52D and 52C as etching stop layers. In the resulting structure, the dielectric layer 52C is exposed in the regions 60, and the dielectric layer 52D is exposed in the regions 62.

In FIG. 8, the photoresist 56 is trimmed to expose additional portions of the multi-layer stack 58. In some embodiments, the photoresist 56 is trimmed by a lateral etching. As a result of the trimming, a width of the photoresist 56 is reduced, and portions the multi-layer stack 58 in the regions 60, the regions 62, and regions 64 may be exposed. For example, top surfaces of the dielectric layer 52C may be exposed in the regions 60; top surfaces of the dielectric layer 52D may be exposed in the regions 62; and top surfaces of the dielectric layer 52E may be exposed in the regions 64.

In FIG. 9, portions of the dielectric layers 52E, 52D, and 52C and the sacrificial layers 53D, 53C, and 53B in the regions 60, the regions 62, and the regions 64 are removed by an etching process using the photoresist 56 as a mask. The etching may include a dry etch, a wet etch, or a combination thereof. The etching may extend the openings 61 further into the multi-layer stack 58. Because the dielectric layers 52C-52E and the sacrificial layers 53B-53D have different material compositions, etchants used to remove exposed portions of these layers may be different. In some embodiments, portions of the dielectric layers 52E, 52D and 52C in the regions 64, 62 and 60 are removed by using the photoresist 56 as a mask and using the underlying sacrificial layers 53D, 53C and 53B as etch stop layers. Thereafter, the exposed portions of the sacrificial layers 53D, 53C and 53B in the regions 64, 62 and 60 are removed by using the photoresist 56 as a mask and using the underlying dielectric layers 52D, 52C and 52B as etching stop layers. In the resulting structure, the dielectric layer 52B is exposed in the regions 60; the dielectric layer 52C is exposed in the regions 62; and the dielectric layer 52D is exposed in the regions 64.

In FIG. 10, the photoresist 56 is trimmed to expose additional portions of the multi-layer stack 58. In some embodiments, the photoresist 56 is trimmed by a lateral etching. As a result of the trimming, a width of the photoresist 56 is reduced, and portions the multi-layer stack 58 in the regions 60, the regions 62, the regions 64, and regions 66 may be exposed. For example, top surfaces of the dielectric layer 52B may be exposed in the regions 60; top surfaces of the dielectric layer 52C may be exposed in the regions 62; and top surfaces of the dielectric layer 52D may be exposed in the regions 64; and top surfaces of the dielectric layer 52E may be exposed in the regions 66.

In FIG. 11, portions of the dielectric layers 52E, 52D, 52C, and 52B in the regions 60, the regions 62, the regions 64, and the regions 66 are removed by an etching process using the photoresist 56 as a mask. The etching may include a dry etch, a wet etch, or a combination thereof. The etching may extend the openings 61 further into the multi-layer stack 58. In some embodiments, portions of the dielectric layers 52E, 52D, 52C and 52B in the regions 66, 64, 62 and 60 are removed by using the photoresist 56 as a mask and using the underlying sacrificial layers 53D, 53C, 53B and 53A as etch stop layers. In the resulting structure, the sacrificial layer 53A is exposed in the regions 60; the sacrificial layer 53B is exposed in the regions 62; the sacrificial layer 53C is exposed in the regions 64; and the sacrificial layer 53D is exposed in the regions 66. Thereafter, the photoresist 56 may be removed.

In FIG. 12, an inter-metal dielectric (IMD) 70 is deposited over the multi-layer stack 58. The IMD 70 may be formed of a dielectric material, and may be deposited by any suitable method, such as CVD, PECVD, flowable CVD (FCVD), or the like. The dielectric materials may include phospho-silicate glass (PSG), boro-silicate glass (BSG), boron-doped phospho-silicate glass (BPSG), undoped silicate glass (USG), or the like. In some embodiments, the IMD 70 may include an oxide (e.g., silicon oxide or the like), a nitride (e.g., silicon nitride or the like), the like, or a combination thereof. The IMD 70 extends along sidewalls of the sacrificial layers 53B-53D and sidewalls of the dielectric layers 52B-52E. Further, the IMD 70 may contact top surfaces of the sacrificial layers 53A-53D.

Thereafter, a planarization process is performed to the IMD 70 to remove excess dielectric material over the multi-layer stack 58. In some embodiments, the planarization process includes a chemical mechanical polish (CMP), an etching back process, the like, or a combination thereof. Accordingly, the top surface of the multi-layer stack 58 is flush with the top surface of the IMD 70 after the planarization process is completed.

Accordingly, an intermediate bulk staircase structure is formed. The intermediate staircase structure includes alternating layers of sacrificial layers 53 and dielectric layers 52. The sacrificial layers 53 are subsequently replaced with conductive layers 72, which will be described in details in FIG. 16A and FIG. 16B. Lower conductive layers 72 are longer and extend laterally past upper conductive layers 72, and a width of each of the conductive layers 72 increases in a direction towards the substrate (see FIG. 1A).

FIG. 13 to FIG. 16B illustrate manufacturing a memory structure in a memory region MR of the ferroelectric memory device 200A, in accordance with some embodiments. In FIG. 13 to FIG. 16B, the bulk multi-layer stack 58 is patterned to form trenches 86 therethrough, and sacrificial layers 53 are replaced with conductive materials to define the conductive layers 72. The conductive layers 72 may correspond to word lines in the ferroelectric memory device 200A, and the conductive layers 72 may further provide gate electrodes for the resulting memory cells of the ferroelectric memory device 200A.

In FIG. 13, photoresist patterns 82 and underlying hard mask patterns 80 are formed over the multi-layer stack 58. In some embodiments, a hard mask layer and a photoresist layer are sequentially formed over the multi-layer stack 58. The hard mask layer may include, for example, silicon nitride, silicon oxynitride, or the like, which may be deposited by CVD, PVD, ALD, PECVD, or the like. The photoresist layer is formed by a spin-on technique, for example.

Thereafter, the photoresist layer is patterned to form photoresist patterns 82 and trenches 86 between the photoresist patterns 82. The photoresists is patterned by a photolithography technique. The patterns of the photoresist patterns 82 are then transferred to the hard mask layer to form hard mask patterns 80 by using an etching process. Thus, trenches 86 are formed extending through the hard mask layer. Thereafter, the photoresist 82 may be optionally removed.

FIG. 14 to FIG. 15B illustrate transferring the patterns of the hard mask patterns 80 to the multi-layer stack 58 using one or more etching processes. Thus, the trenches 86 extend through the bulk multi-layer stack 58, and strip-shaped sacrificial layers 53 and strip-shaped dielectric layers 52 are accordingly defined. In some embodiments, the trenches 86 extend through the bulk staircase structure, and strip-shaped staircase structures are accordingly defined. The hard mask patterns 80 may be then removed by an etching process, a planarization process, the like, or a combination thereof.

FIG. 15A to FIG. 16B illustrate replacing the sacrificial layers 53A-53D (collectively referred to as sacrificial layers 53) with conductive layers 72A-72D (collectively referred to as conductive layers 72). In some embodiments, the sacrificial layers 53 are removed by an etching process. Thereafter, conductive layers 72 are formed in the space between two adjacent dielectric layers 52. In some embodiments, each conductive layer 72 includes W, TiN, Cu, Al, Au, Pt, the like or a combination thereof. In some embodiments, each conductive layer 72 is a multi-layer structure including a metal layer (e.g., W) and a barrier layer (e.g., TiN) disposed between the metal layer and the adjacent dielectric layer 52. The barrier layer and the metal layer are further deposited on the sidewalls of the multi-layer stack 58 and fill in the trenches 86. Thereafter, the barrier layer and the metal layer in the trenches 86 are removed by an etching back process. In some embodiments, upon the replacement process, the sacrificial layers 53 of the strip-shaped staircase structures are subsequently replaced with conductive layers 72 (see FIG. 1A). Each conductive layer 72 may has a thickness of about 50-10,000 nm.

FIG. 17A and FIG. 17B illustrate recessing the conductive layers 72 exposed by the sidewalls of the trenches 86 and therefore forming recesses 87. Specifically, one of the recesses 87 is formed between two adjacent dielectric layers 52. Each recess 87 is a space surrounded by one conductive layer 72 and two adjacent dielectric layers 52. The recesses 87 are connected to (e.g., in spatial communication with) the corresponding trenches 86. Specifically, the sidewalls of the dielectric layers 52 are recessed, by about 1-100 nm (e.g., 5-10 nm) with respect to the sidewalls of the conductive layers 72 exposed by the trenches 86. In some embodiments, the conductive layers 72 of the multi-layer stack 58 are trimmed by a lateral etching. The etching may include a dry etch, a wet etch, or a combination thereof. In some embodiments, when the conductive layers 72 include W, the etchants include NH₄OH, H₂O₂ and H₂O. In some embodiments, when the conductive layers 72 include Al, the etchants include H₃PO₄, HNO₃ and CH₃COOH. In some embodiments, H₃PO₄, HNO₃ and CH₃COOH are added in a ratio of (75-85):(1-5):(10-24). For example, H₃PO₄, HNO₃ and CH₃COOH are added in a ratio of 85:2:13. Upon the recessing process, the multi-layer stack 58 has a curvy sidewall. Specifically, the ends of the dielectric layers 52 are protruded from the ends of the remaining conductive layers 72.

FIG. 18A, FIG. 18B and FIG. 18C illustrate forming a ferroelectric layer 90 on the sidewalls of the trenches 86 and filling in the recesses 87. The ferroelectric layer 90 is a continuous ferroelectric layer. In some embodiments, the ferroelectric layer 90 may be deposited conformally along the sidewalls of the trenches 86 (e.g., sidewalls of the dielectric layers 52), along the top surfaces of the recesses 87 (e.g., exposed bottom surfaces of the dielectric layers 52), along the side surfaces of the recesses 87 (e.g., sidewalls of the conductive layers 72), along the bottom surfaces of the recesses 87 (e.g., exposed top surfaces of the dielectric layers 52), and along the bottom surfaces of the trenches 86.

The ferroelectric layer 90 may include materials that are capable of switching between two different polarization directions by applying an appropriate voltage differential across the ferroelectric layer 90. For example, the ferroelectric layer 90 includes a high-k dielectric material, such as a hafnium (Hf) based dielectric materials or the like. In some embodiments, the ferroelectric layer 90 includes hafnium oxide, hafnium zirconium oxide, silicon-doped hafnium oxide, or the like. In some embodiments, the ferroelectric layer 90 is hafnium oxide (HfO₂) doped by Al, Si, Zr, La, Gd, or Y, in an embodiment. In some embodiments, a ferroelectric material, such as HZO, HSO, HfSiO, HfLaO, HfZrO₂ (HZO), or ZrO₂, is used as the ferroelectric material. For example, the ferroelectric layer 90 includes HfO₂, Zr-doped HfO₂, Al-doped HfO₂, KNO₃, BiFcO₃, BiMnO₃, YMnO₃, TbMnO₃, PbZr₍₁₋ₓ₎TiₓO₃, Pb(Zr,Ti)O₃, Pb(Sc_{1/2}Ta_{1/2})O₃, Pb(Sc_{1/2}Nb_{1/2})O₃, Pb(Mg_{1/3}Nb_{2/3})O₃, Pb(Zn_{1/3}Nb_{2/3})O₃, LiTaO₃, LiNbO₃, Sr_{0.8}Bi_{2.2}Ta₂O₉, SrBi₂Nb₂O₉, PbTiO₃, BaTiO₃, SrTiO₃, LiTiO₃, LiNbO₃, BcFcO₃, KNbO₃, KTaO₃, CaTiO₃, GdFcO₃, DyScO₃, Bi₂O₂, Bi₂WO₆, SrBi₂Ta₂O₉, Bi₄Ti₃O₁₂, SrBi₂Ta₂O₉, Mn₃TeO₆, Pb₅Ge₃O₁₁, Gd₂(MoO₄)₃, R₃Sb₅O₁₂, LiNaGe₄O₉, BaAl₂O₄, Li₂Ge₇O₁₅, KNO₃, YMnO₃, SmB₆, BaBiO₃, LuFe₂O₄, YFC₂O₄, Fe₂BO₄, La_{1.5}Sr_{0.5}NiO₄, PbTiO₃, or a combination thereof. In some embodiments, the ferroelectric layer 90 is a single layer. In other embodiments, the ferroelectric layer 90 is a multi-layer structure. A suitable formation method, such as PVD, CVD, ALD, or the like, may be used to form the ferroelectric layer 90. The ferroelectric layer 90 may have a thickness of about 1-1,000 nm. In some embodiments, an annealing process is optionally performed to the ferroelectric layer 90 as needed. The temperature range of the annealing process ranges from about 300° C. to about 450° C., so as to achieve a desired crystalline lattice structure for the ferroelectric layer 90.

FIG. 18A, FIG. 18B and FIG. 18C illustrate forming a channel layer 91 on the ferroelectric layer 90 and filling in the recesses 87. The channel layer 91 is a continuous channel layer. In some embodiments, the channel layer 91 may be deposited conformally on the ferroelectric layer 90, along the sidewalls of the trenches 86 (e.g., sidewalls of the dielectric layers 52), along the top surfaces of the recesses 87 (e.g., exposed bottom surfaces of the dielectric layers 52), along the side surfaces of the recesses 87 (e.g., sidewalls of the conductive layers 72), along the bottom surfaces of the recesses 87 (e.g., exposed top surfaces of the dielectric layers 52), and along the bottom surfaces of the trenches 86. The channel layer 91 includes materials suitable for providing channel regions for the memory cells 202 (see FIG. 1A). For example, the channel layer 91 includes oxide semiconductor (OS) such as zinc oxide (ZnO), indium tungsten oxide (InWO), indium gallium zinc oxide (InGaZnO, IGZO), indium zinc oxide (InZnO), indium tin oxide (ITO), the like, or a combination thereof. In some embodiments, channel layer 91 includes polycrystalline silicon (poly-Si), amorphous silicon (a-Si), or the like. The channel layer 91 may be deposited by CVD, PVD, ALD, PECVD, or the like. The channel layer 91 may have a thickness of about 1-500 nm. In some embodiments, an annealing process is optionally performed to the channel layer 91 as needed. The temperature range of the annealing process ranges from about 300° C. to about 450° C., so as to activate the charge carriers of the channel layer 91.

The channel layer 91 may include an N-type channel material or a P-type channel material. In some embodiments, the N-type channel material includes InP, GaP, GaN, GaSb, GaAs, AlAs, InAs, InSb, AlGaAs, Si, Ge, SiGe, InGaZnO, InOₓ, GaZnOₓ, InGaSnOₓ, GaInAs, GaInP, InAlAs, InGaAs, AllInGaP, SnOₓ, Si, Ge, C, SiC, SiGe, SiGeC, GaAs, In-rich GaAs (In_{0.65}Ga_{0.35}As), InP, GaP, GaN, GaSb, GaAs, AlAs, InAs, InSb, AlGaAs, GaInAs, GaInP, InAlAs, InGaAs, AlInGaP, CdS, CdSe, CdTe, ZnS, ZnSe, ZnTe, PbS, PbTe, HgTe, IGZO, or a combination thereof. In some embodiments, the P-type channel material includes NiO, SnO, CuzO, K₂Sn₂O₃, doped Al:NiO, V:NiO, Cu:NiO, Sn:NiO, Mg:NiO, Li:MgNiO, K₂Sn₂O₃, RbSn₂O₃, TiSnO₃, Sns(PO₅)₂, Ta₂Sn₂O₆, Pb:CsSnI₃, CuCrO₂, Mg:Cu₂O, CuFeO₂, CsPbIBr₂, PCBM, TiSnO₃, Sns(PO₅)₂, Ta₂SnO₆, Cs—NiOₓ, BCP (bathocuproine), or a combination thereof.

In some embodiments, each of the ferroelectric layer 90 and the channel layer 91 has a uniform thickness, as shown in FIG. 18B. Specifically, portions of the ferroelectric layer 90 and portions of the channel layer 91 on the dielectric layers 52 are as thick as portions of the ferroelectric layer 90 and portions of the channel layer 91 in the recesses 87 adjacent to the conductive layers 72. However, the disclosure is not limited thereto.

In other embodiments, each of the ferroelectric layer 90 and the channel layer 91 has a varying thickness, as shown in FIG. 18C. Specifically, portions of the ferroelectric layer 90 and portions of the channel layer 91 on the dielectric layers 52 are thicker than portions of the ferroelectric layer 90 and portions of the channel layer 91 in the recesses 87 adjacent to the conductive layers 72.

FIG. 19A, FIG. 19B and FIG. 19C illustrate performing an etching back process to remove the channel layer 91 outside of the recesses 87. In some embodiments, an etching back process is performed to the continuous channel layer 91, so as to remove excess materials from the sidewalls of the dielectric layers 52 and the bottom surfaces of the trenches 86. The etching may include a dry etch, a wet etch, or a combination thereof. In some embodiments, the etching is a select anisotropic etching which partially removes the channel layer 91 without removing the ferroelectric layer 90.

Upon the etching back process, the continuous channel layer 91 is divided into multiple separate channel segments 92A-92D. The separate channel segments 92A-92D are embedded in the recesses 87 adjacent to the conductive layers 72A-72D, respectively. In some embodiments, the separate channel segments 92A-92D are referred to as a discontinuous channel layer 92, and portions of the channel layer 92 are embedded in the recesses 87, respectively. FIG. 19B shows the resulting structure after performing the etching back process to the structure of FIG. 18B. FIG. 19C shows the resulting structure after performing the etching back process to the structure of FIG. 18C. Please note that the ferroelectric layer 90 with a varying thickness may be applied to the following structures.

FIG. 20 illustrates forming a dielectric material 98 in the trenches 86 and over the channel segments 92A-92D in the recesses 87. In some embodiments, the dielectric material 98 completely fills the trenches 86 and the recesses 87. In some embodiments, the dielectric material 98 includes silicon oxide, silicon nitride, silicon oxynitride, or the like, which may be deposited by CVD, PVD, ALD, PECVD, or the like.

FIG. 21A and FIG. 21B illustrates performing a planarization process to the dielectric material 98. In some embodiments, the planarization process includes CMP, an etching back process, the like, or a combination thereof. In some embodiments, upon the planarization process, the top surfaces of the remaining dielectric material 98 and the ferroelectric layer 90 are substantially level (e.g., within process variations). In some embodiments, portions of the dielectric material 98 (referred to as dielectric segments 99) are embedded in the recesses 87, respectively.

FIG. 22A and FIG. 22B illustrate pattering the dielectric material 98 to form trenches 100 penetrating through the dielectric material 98. The patterning process may include photolithography etching processes. The trenches 100 may be disposed between opposing sidewalls of the ferroelectric layer 90, and the trenches 100 may physically separate adjacent stacks of memory cells in the memory array.

FIG. 23A and FIG. 23B illustrate forming isolation pillars 102 in the trenches 100. In some embodiments, an isolation layer is deposited over the multi-stack 58 filling in the trenches 100. The isolation layer may include, for example, silicon oxide, silicon nitride, silicon oxynitride, or the like, which may be deposited by CVD, PVD, ALD, PECVD, or the like. After deposition, a planarization process (e.g., a CMP, etching back, or the like) may be performed to remove excess portions of the isolation layer. In the resulting structure, the top surfaces of the ferroelectric layer 90, the dielectric material 98, and the isolation pillars 102 may be substantially level (e.g., within process variations). In some embodiments, materials of the dielectric material 98 and isolation pillars 102 may be selected so that they may be etched selectively relative each other. In some embodiments, the dielectric material 98 include silicon oxide and the isolation pillars 102 include silicon nitride. In other embodiments, the dielectric material 98 include silicon nitride and the isolation pillars 102 include silicon oxide. When silicon oxide is etched, the etchants may include CF₄, C₂F₆, C₃F₈, CHF₃, O₂, H₂ or a combination thereof. When silicon nitride is etched, the etchants may include CF₄, SF₆, CHF₃, NF₃, O₂ or a combination thereof. Other materials are also possible.

FIG. 24A and FIG. 24B illustrate forming conductive pillars 106 and 108 at two opposites of each of the isolation pillars 102. In some embodiments, the dielectric material 98 are patterned to form openings (not shown) penetrating through the dielectric material 98. The patterning process may include photolithography etching processes. Thereafter, a conductive material is formed in the openings. The conductive material may include copper, titanium, titanium nitride, tantalum, tantalum nitride, tungsten, ruthenium, aluminum, the like, or a combination thereof. For example, the conductive material may include Se, Pt, Ir, Ni, Au, Co, C, Be, Rh, Re, Te, Si, Os, Ru, Cu, Mo, Sb, W, Cr, Fc, Hg, B, Sn, Ti, Zn, Nb, V, Al, Ag, Pb, Ta, Bi, Cd, Ga, In, Mn, Zr, Hf, Tl, As, Mg, U, La, Sc, Th, Lu, Nd, Gd, Y, Tb, Li, Ce, Ca, Na, Sm, Ba, Sr, Eu, K, Rb, or a combination thereof. The conductive material may be formed using, for example, CVD, ALD, PVD, PECVD, or the like.

After the conductive material is deposited, a planarization (e.g., a CMP, etching back, or the like) may be performed to remove excess portions of the conductive material, thereby forming the conductive pillars 106 and 108. In the resulting structure, the top surfaces of the ferroelectric layer 90, the dielectric material 98, and the isolation pillars 102, and the conductive pillars 106 and 108 may be substantially level (e.g., within process variations).

In some embodiments, two adjacent sides of each of the conductive pillars 106 and 108 are connected to different materials in different cross-sections. In some embodiments, each of the conductive pillars 106 and 108 is in contact with the dielectric material 98 in a first cross-section, while in contact with the ferroelectric layer 90, the channel layer 92 and the dielectric segments 99 in a second cross-section connected to the first cross-section, as shown in the right-bottom corner of FIG. 24A.

Thereafter, more interconnect layers including conductive features in dielectric layers may be disposed over the multi-layer stack 58 and electrically connected to the conductive pillars 106 and 108. For examples, the conductive pillars 106 are electrically coupled to respective bit lines (e.g., conductive lines 116B), and conductive pillars 108 are electrically coupled to respective source lines (e.g., conductive lines 116A), as shown in FIG. 1A and FIG. 1B. Thus, stacked memory cells 202 may be formed in the ferroelectric memory device 200A. Each memory cell 202 includes a gate electrode (e.g., a portion of a corresponding conductive layer 72), a gate dielectric (e.g., a portion of a corresponding ferroelectric layer 90), a channel region (e.g., a portion of a corresponding channel segment 92), and source/drain pillars (e.g., portions of corresponding conductive pillars 106 and 108). The isolation pillars 102 isolates adjacent memory cells 202 in the same column and at the same vertical level. The memory cells 202 may be disposed in an array of vertically stacked rows and columns.

In some embodiments, the operations of FIG. 13 to FIG. 21B in the memory region MR may be applied to the staircase region SR. Accordingly, the staircase structure in the staircase region SR has an element configuration similar to the memory structure in the memory region MR, as shown in the ferroelectric memory device 200A in FIG. 1A.

In other embodiments, the operations of FIG. 13 to FIG. 16B in the memory region MR may be applied to the staircase region SR, while the operations of FIG. 17A to FIG. 21B in the memory region MR may not be applied to the staircase structure in the staircase region SR. Accordingly, the staircase structure in the staircase region SR has an element configuration different from the memory structure in the memory region MR. Specifically, the staircase structure in the staircase region SR is free of the ferroelectric layer 90, the channel segments 92A-92D and the dielectric segments 99.

Although the embodiments of FIG. 1 through FIG. 24B illustrate a particular pattern for the conductive pillars 106 and 108, other configurations are also possible. For example, in these embodiments, the conductive pillars 106 and 108 have a staggered pattern. However, in other embodiments, the conductive pillars 106 and 108 in the same row of the array are all aligned with each other.

In the ferroelectric memory device 200A, a channel layer is cut into multiple channel segments corresponding to multiple gate electrodes. By such configuration, the cell-to-cell noise interference is prevented, the off current (I_{off}) or leaky current of the device is significantly reduced, and the Iₒₙ/I_{off} ratio is accordingly enhanced.

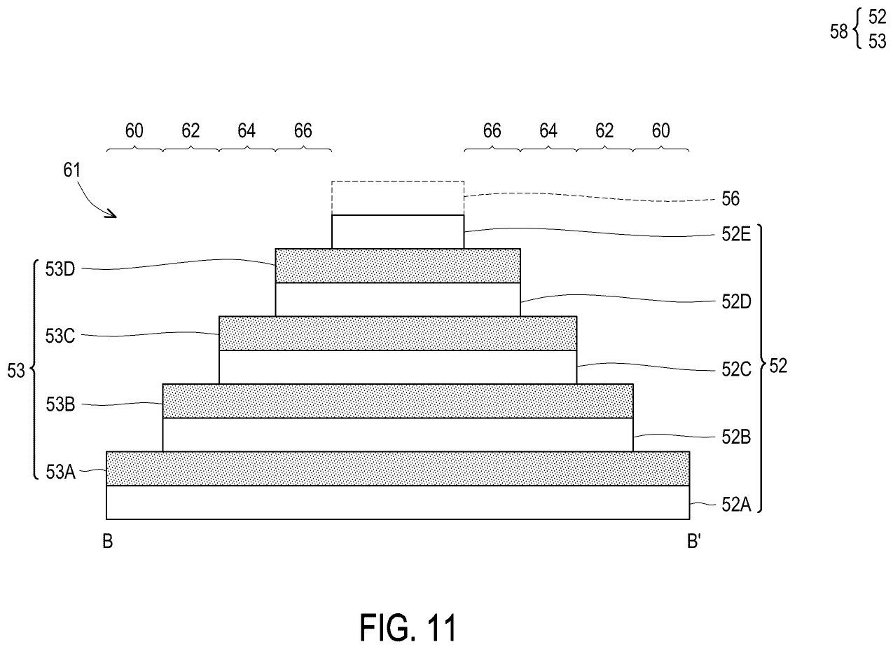

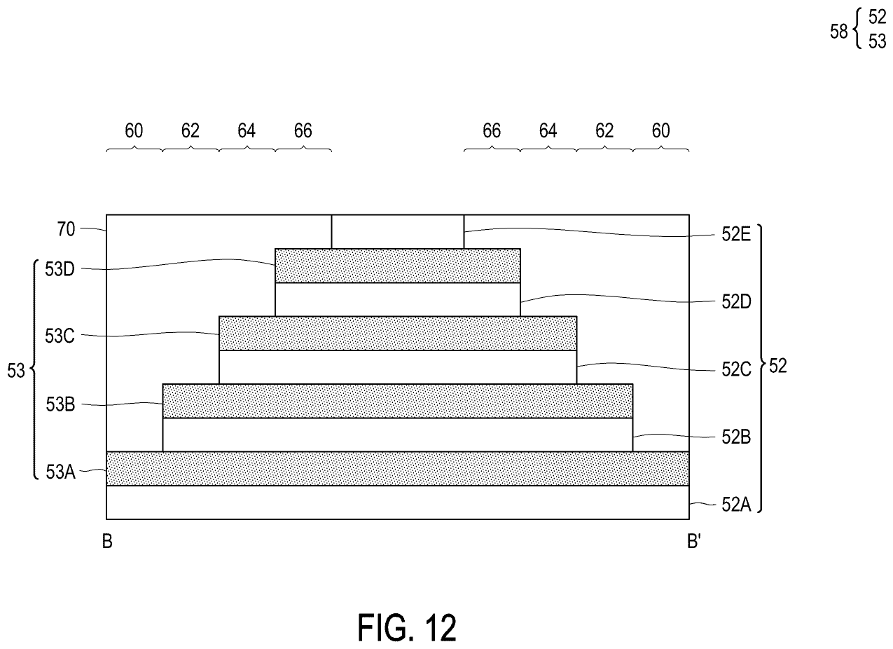

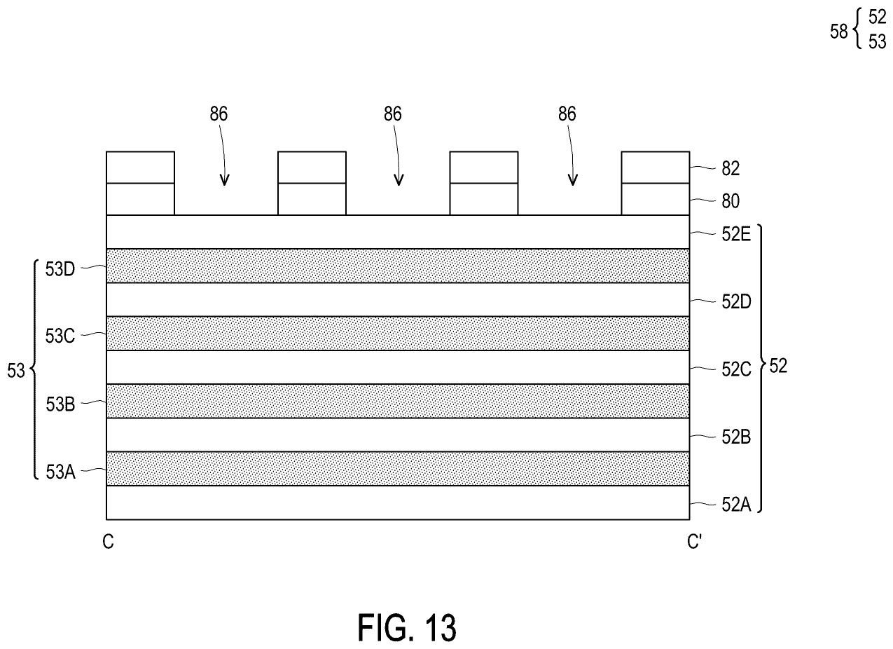

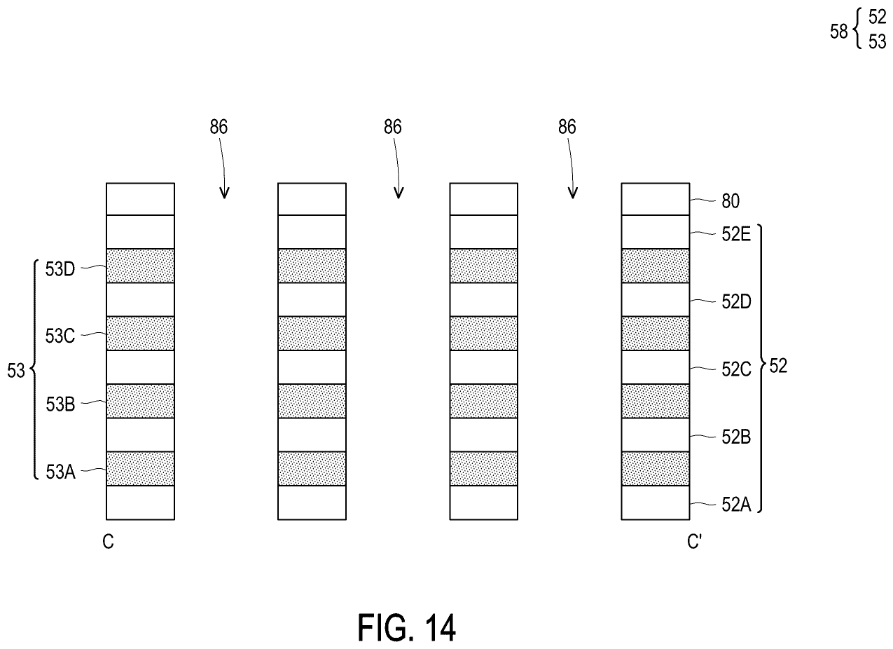

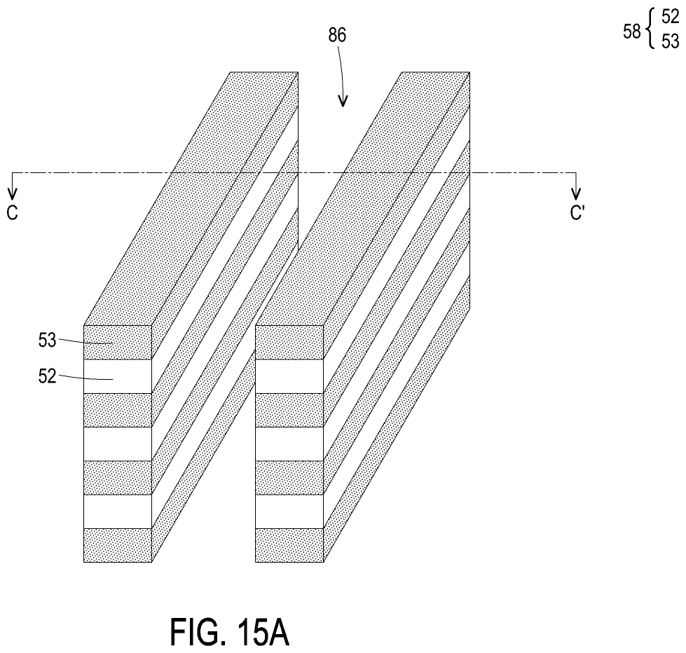

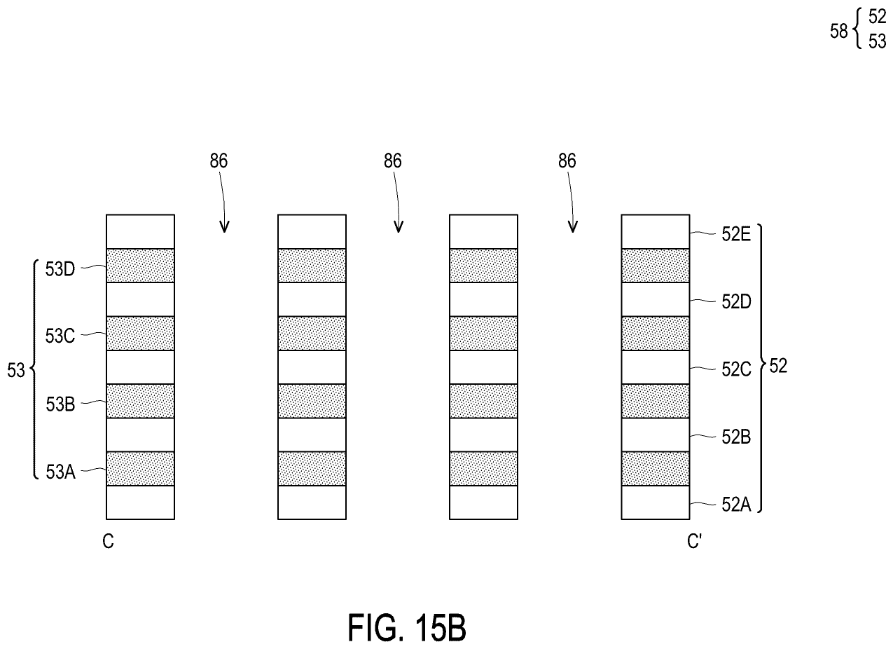

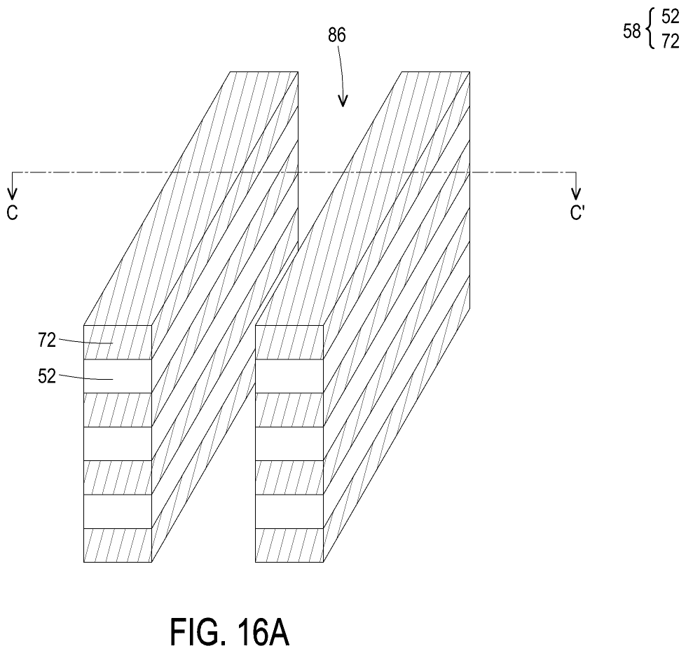

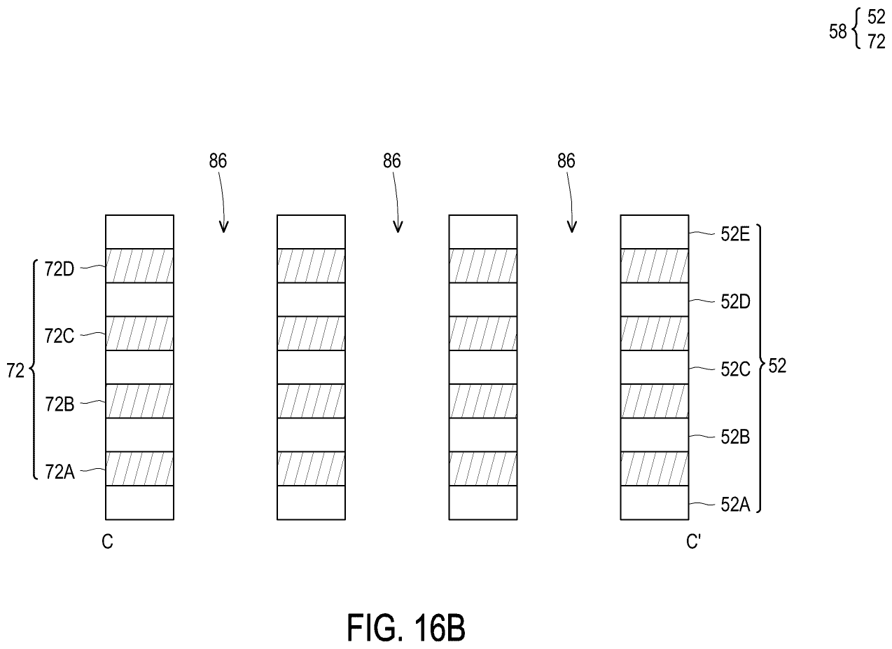

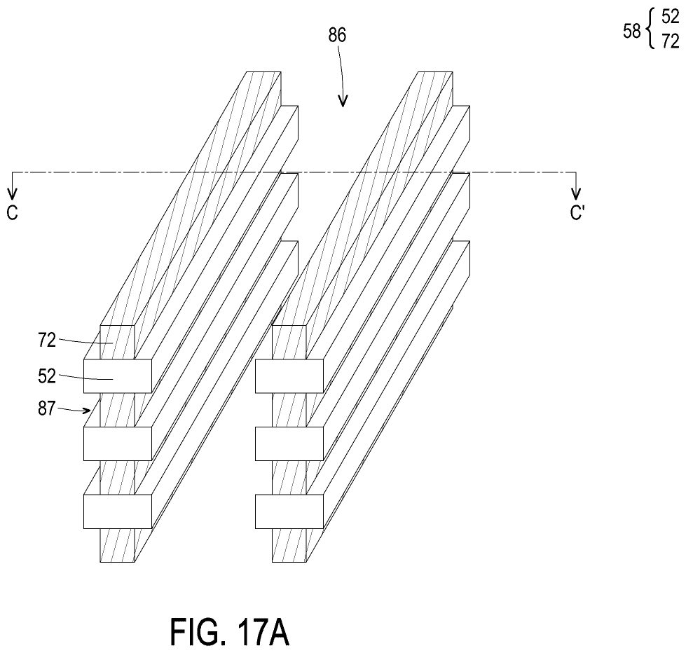

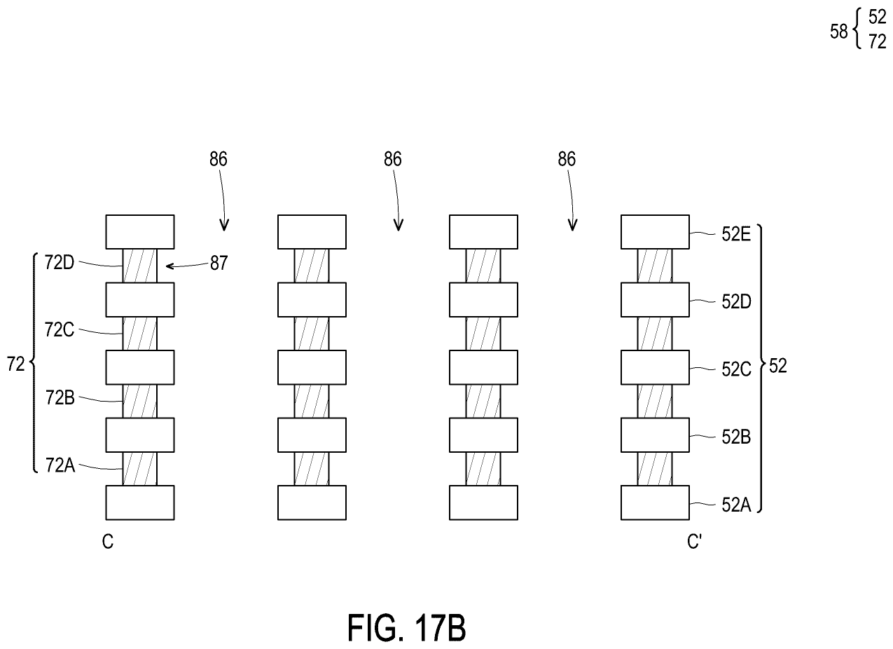

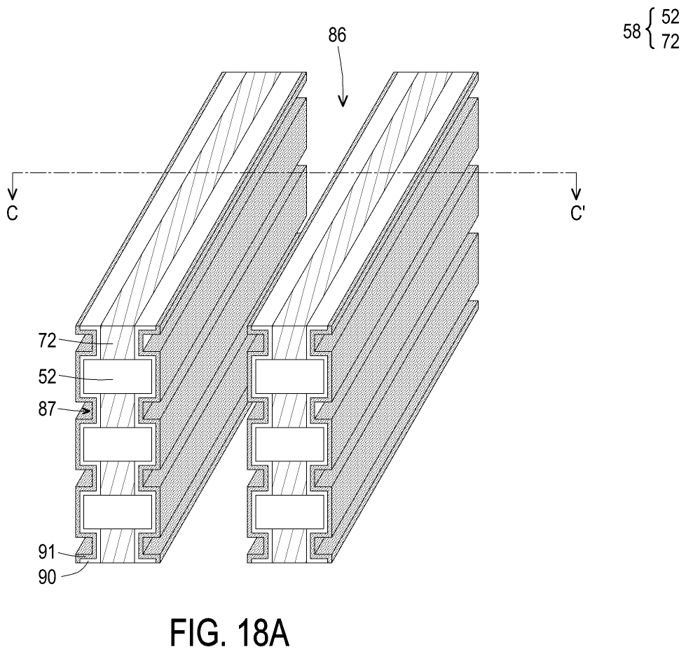

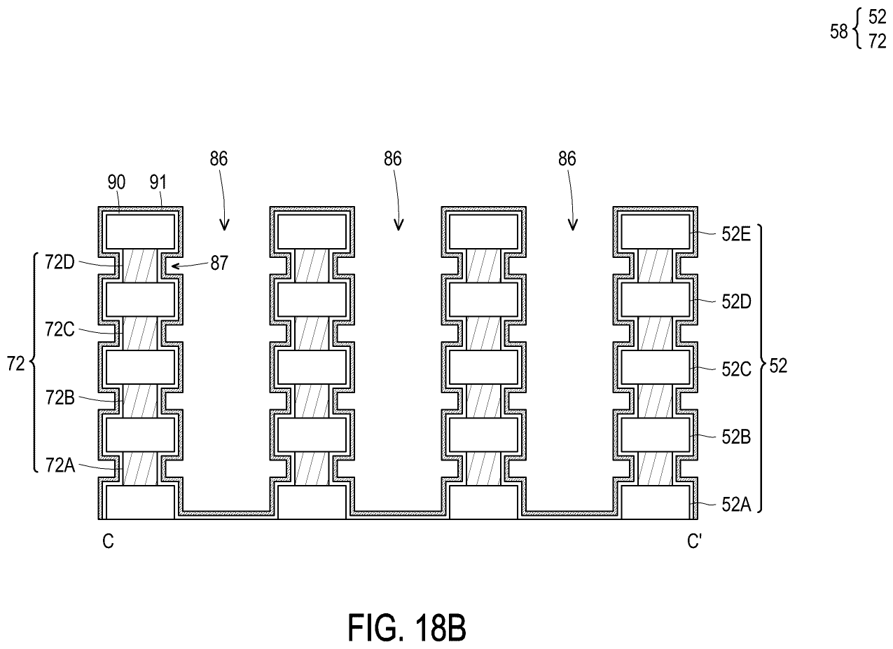

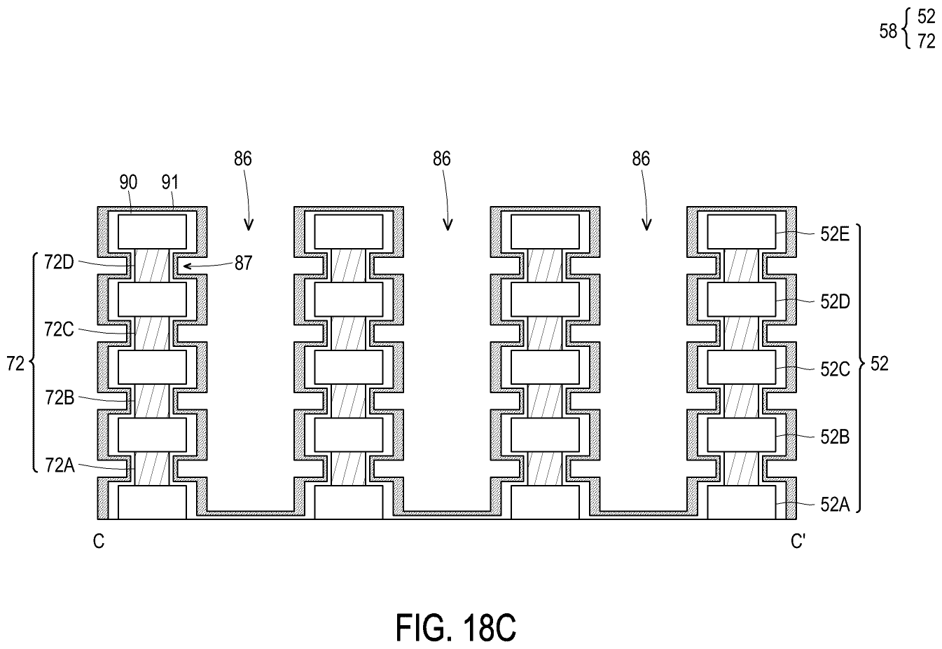

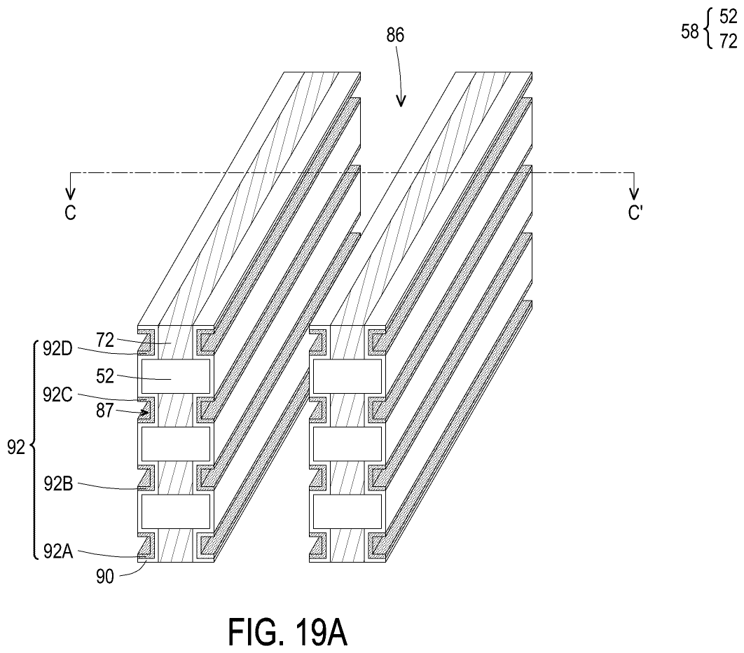

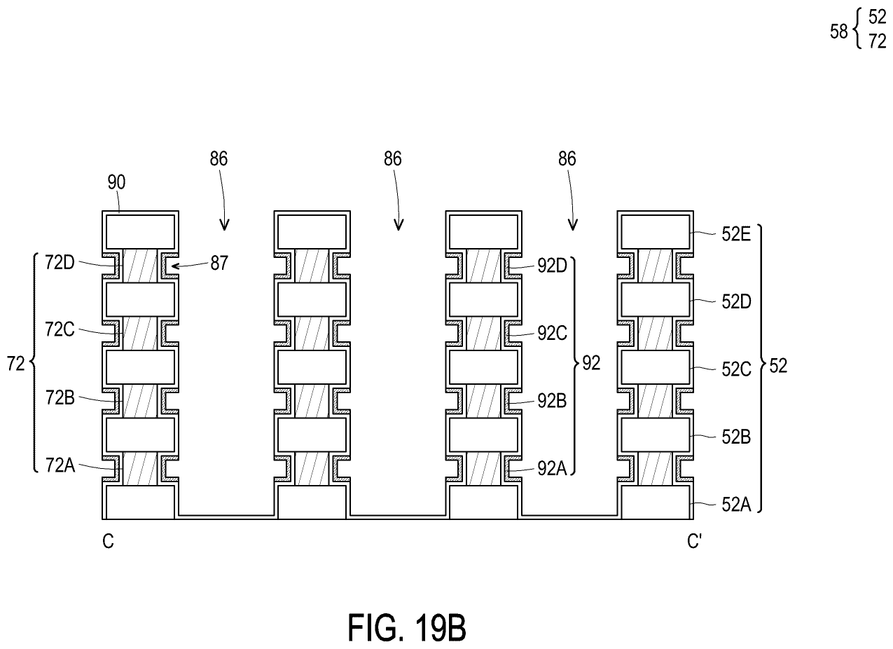

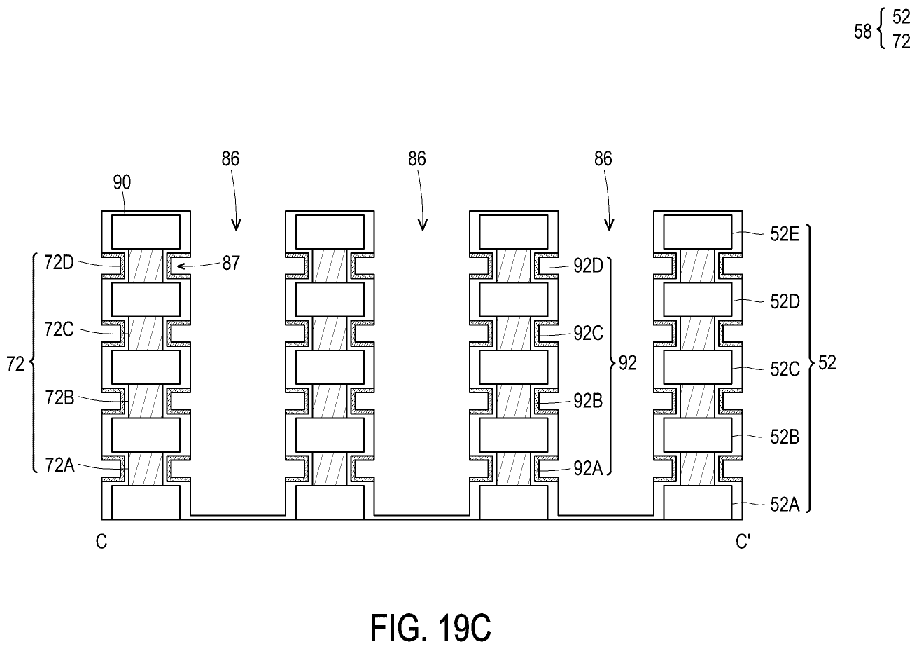

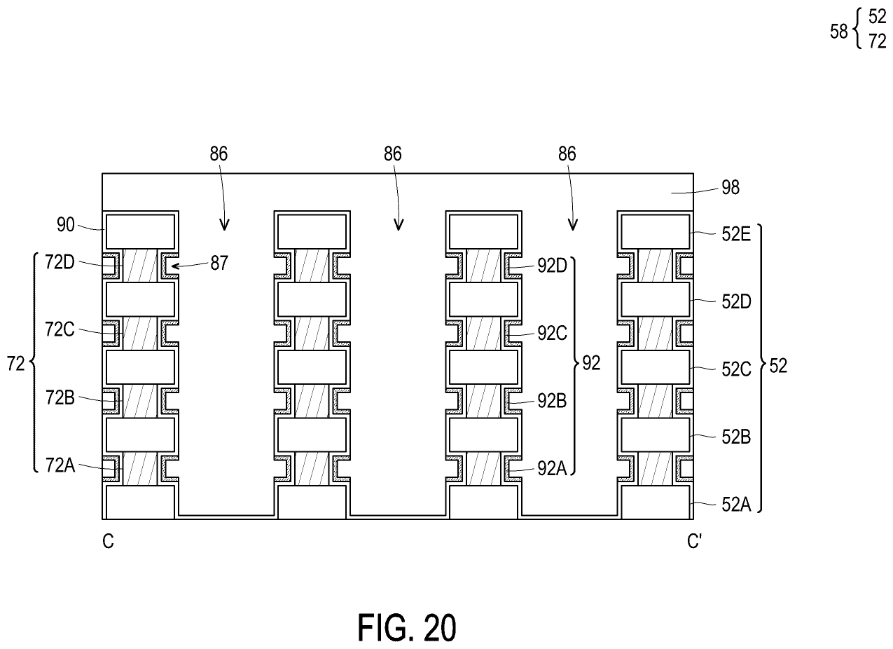

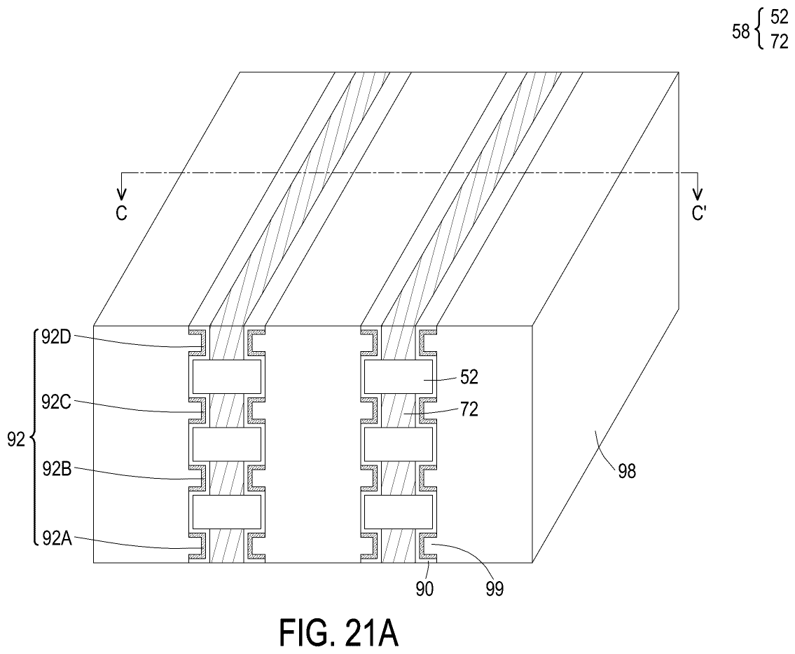

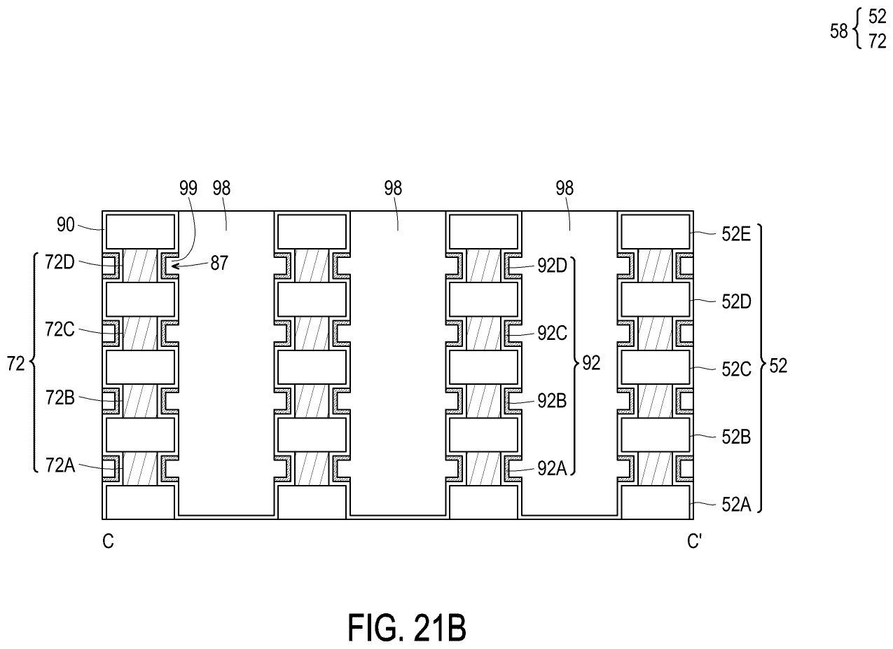

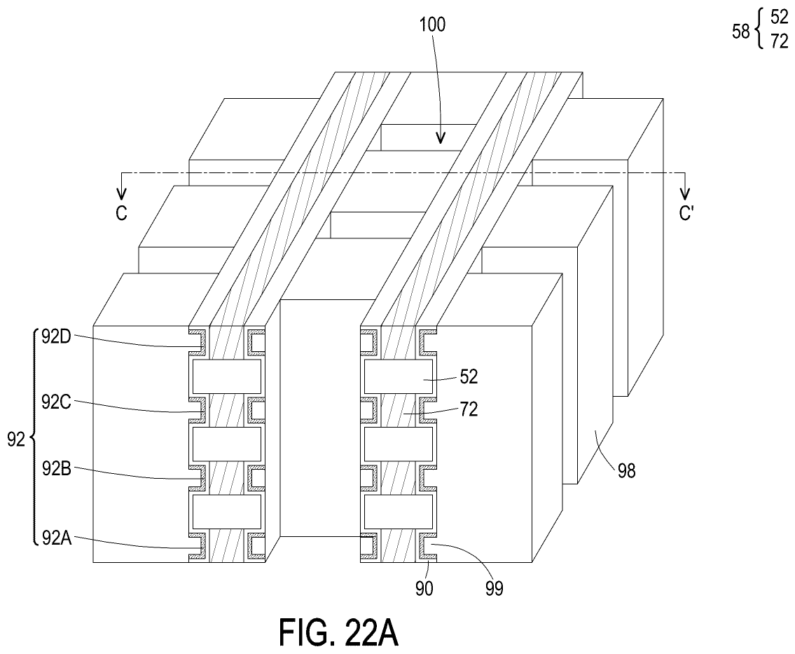

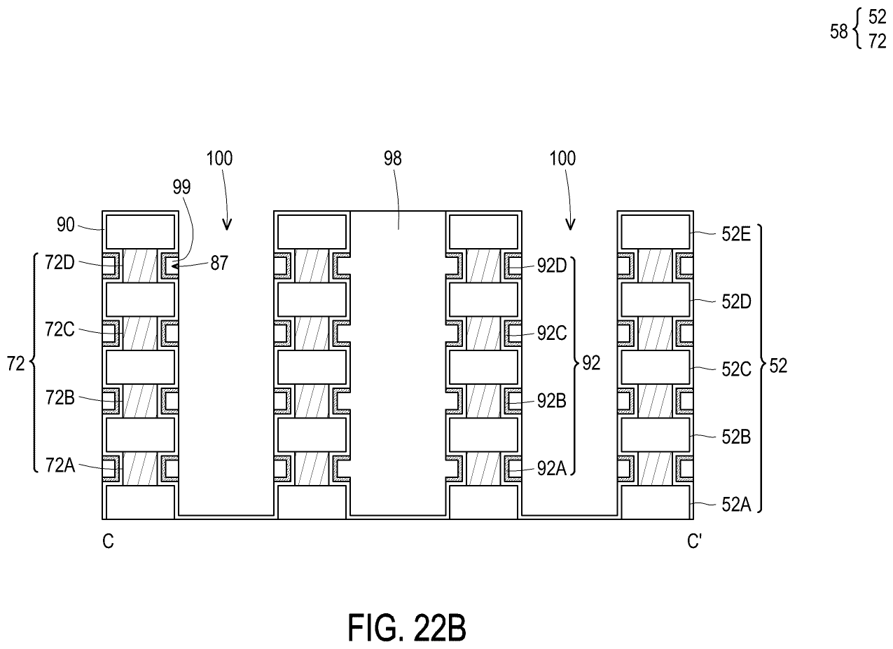

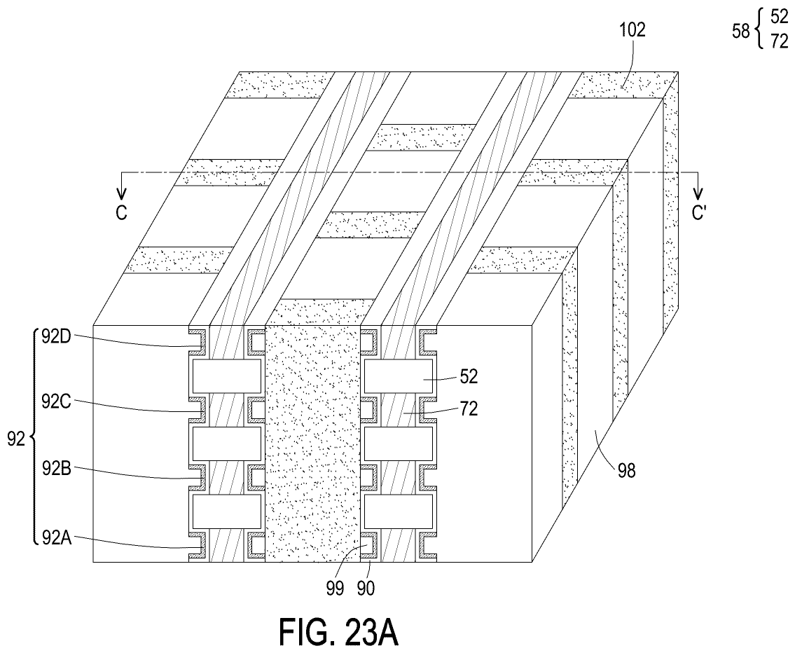

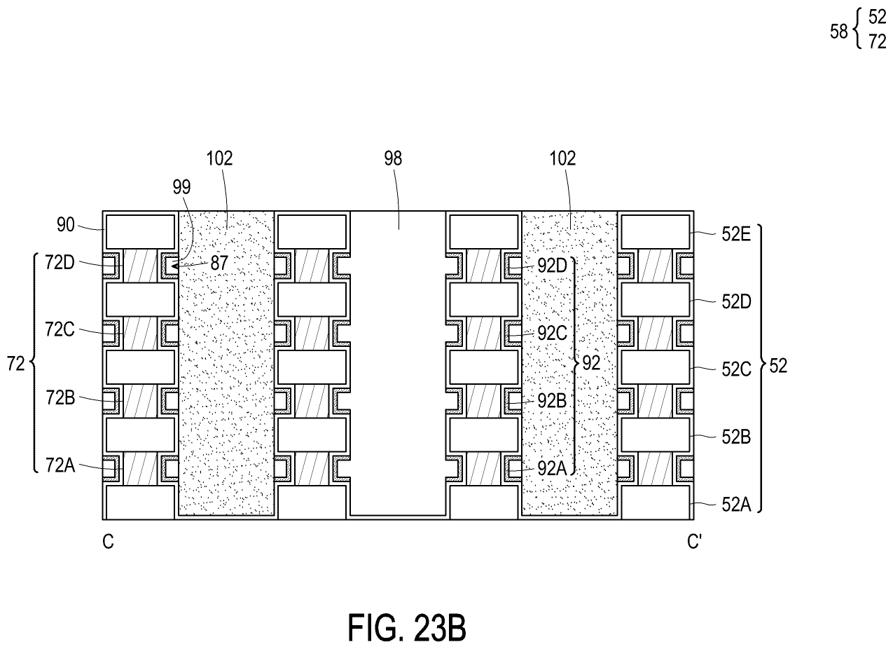

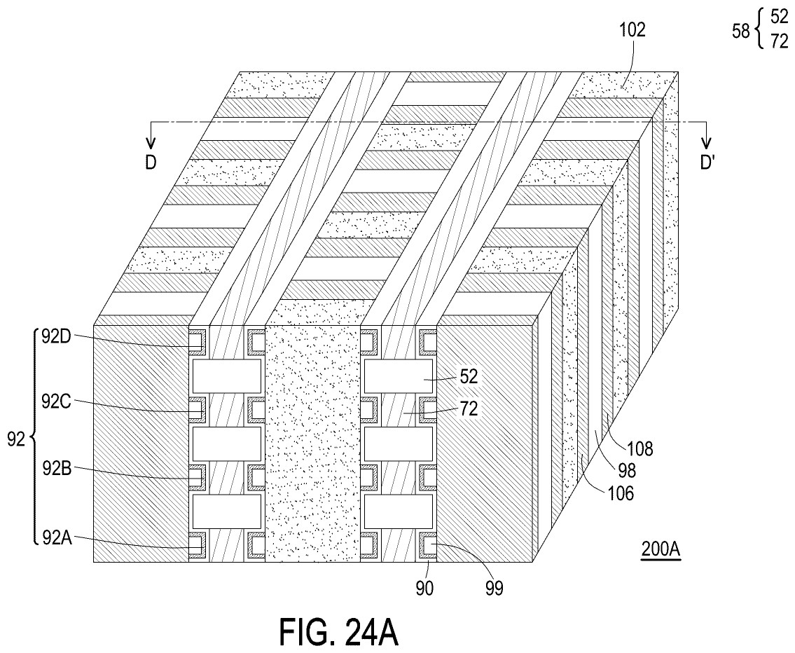

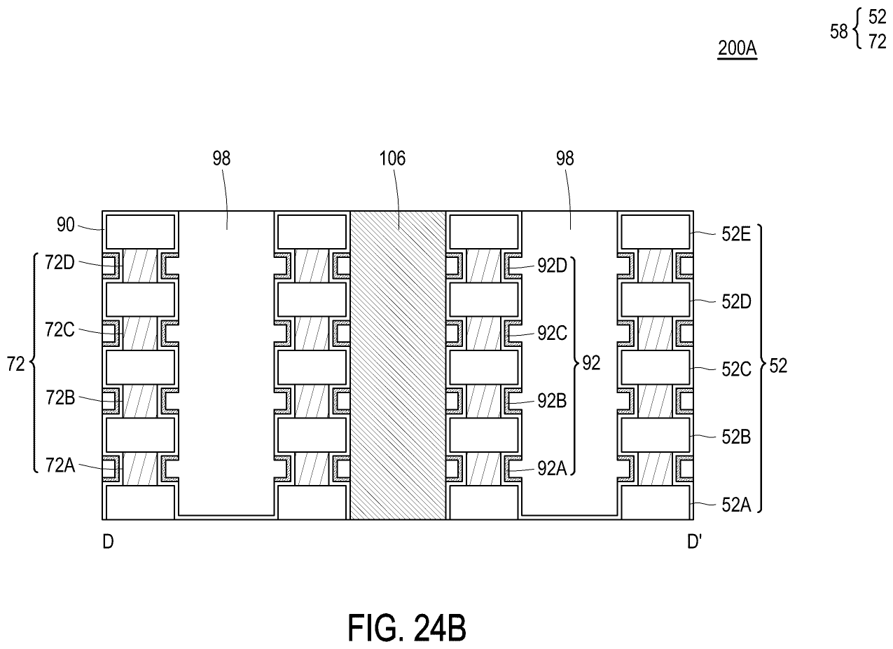

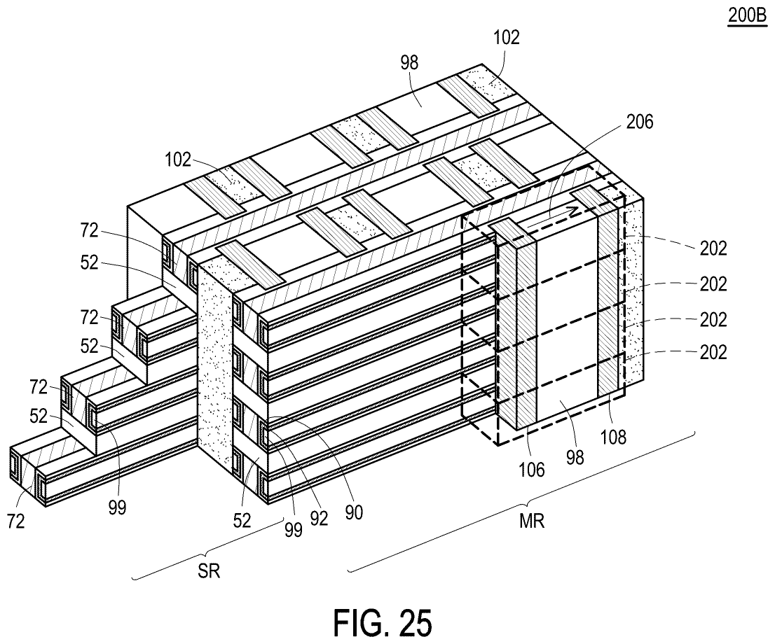

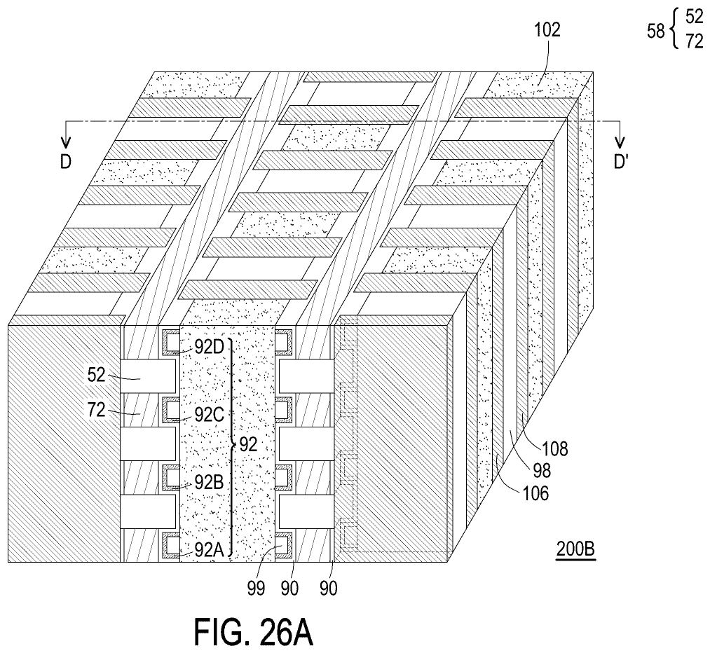

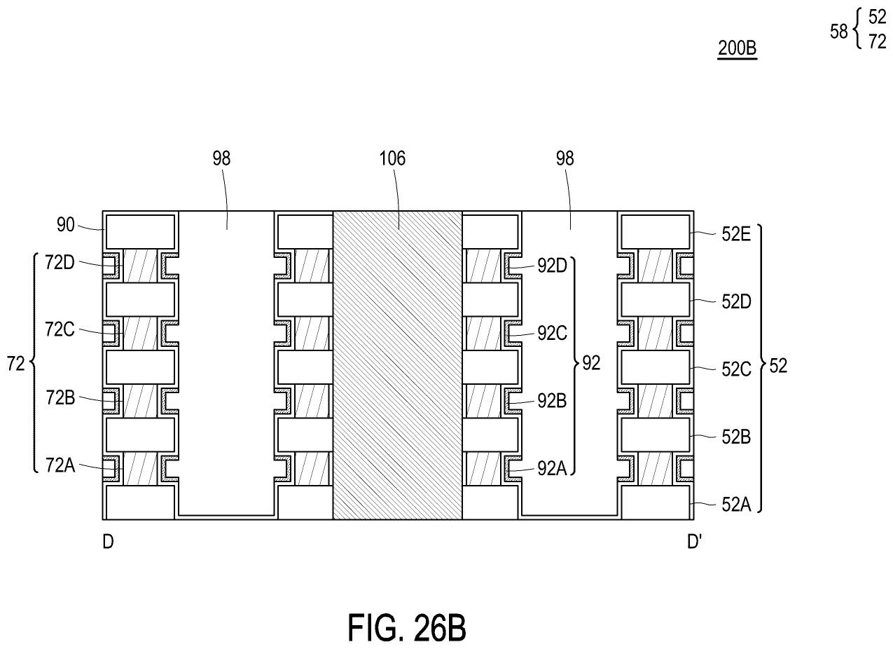

In the ferroelectric memory device 200A, the width of the conductive pillars 106 and 108 are substantially the same with the width of the isolation pillars 102. However, the disclosure is not limited thereto. In other embodiments, the width of the conductive pillars 106 and 108 may be greater than the width of the isolation pillars 102, as shown in FIG. 25 and FIG. 26A to FIG. 26B.

The method of forming the ferroelectric memory device 200B in FIG. 25 and FIG. 26A to FIG. 26B is similar to the method of forming the ferroelectric memory device 200A in FIG. 1A and FIG. 24A to FIG. 24B, so the difference between them is described below, and the similarity is not iterated herein. During the operation of FIG. 24A and FIG. 24B in forming conductive pillars 106 and 108 of the ferroelectric memory device 200B, the width of conductive pillars 106 and 108 may extend beyond the width of the isolation pillars 102. In some embodiments, two adjacent sides of each of the conductive pillars 106 and 108 are connected to different materials in different cross-sections. In some embodiments, each of the conductive pillars 106 and 108 is in contact with the ferroelectric layer 90 in a first cross-section, while in contact with the ferroelectric layer 90, the channel layer 92, the dielectric segments 99 and the dielectric material 98 in a second cross-section connected to the first cross-section, as shown in the right-bottom corner of FIG. 26A.

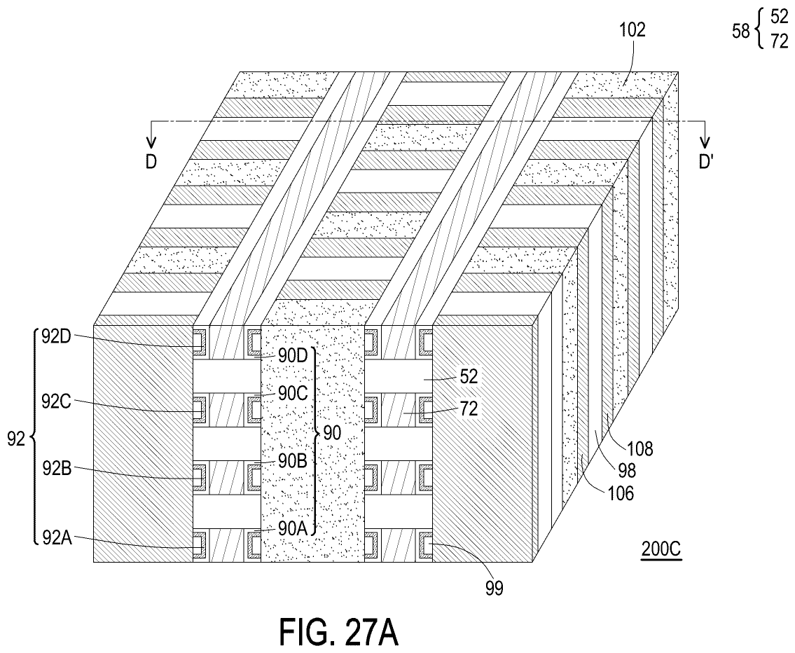

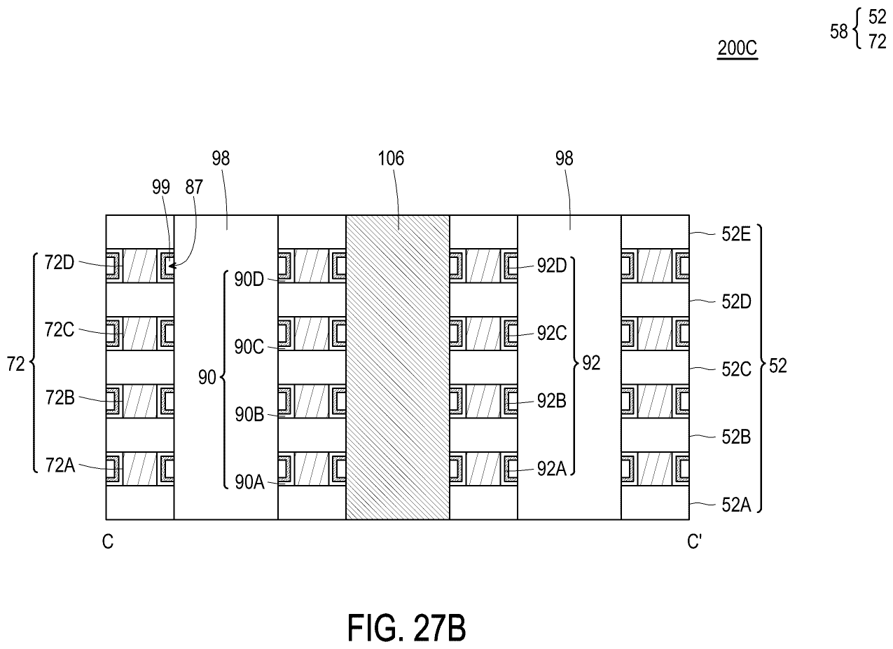

In the above embodiments, only the channel layer is cut into multiple channel segments corresponding to multiple gate electrodes. However, the disclosure is not limited thereto. In other embodiments, both of the channel layer and the ferroelectric layer are cut into multiple channel segments and ferroelectric segments corresponding to multiple gate electrodes, as shown in FIG. 27A to FIG. 27B.

The method of forming the ferroelectric memory device 200C in FIG. 27A to FIG. 27B is similar to the method of forming the ferroelectric memory device 200A in FIG. 24A to FIG. 24B, so the difference between them is described below, and the similarity is not iterated herein. During the operation of FIG. 19A and FIG. 19B in performing an etching back process to remove the channel layer 91 outside of the recesses 87, the etching back process further removes the ferroelectric layer 90 outside of the recesses 87.

Upon the etching back process, the continuous channel layer 91 is divided into multiple separate channel segments 92A-92D. The separate channel segments 92A-92D are embedded in the recesses 87 adjacent to the conductive layers 72A-72D, respectively. In some embodiments, the separate channel segments 92A-92D are referred to as a discontinuous channel layer 92, and portions of the channel layer 92 are embedded in the recesses 87, respectively.

Upon the etching back process, the ferroelectric layer 90 is divided into multiple separate ferroelectric segments 90A-90D. The separate ferroelectric segments 90A-90D are embedded in the recesses 87 between the conductive layers 72A-72D and the channel segments 92A-92D, respectively. In some embodiments, the separate ferroelectric segments 90A-90D are referred to as a discontinuous ferroelectric layer 90, and portions of the ferroelectric layer 90 are embedded in the recesses 87, respectively.

In some embodiments, two adjacent sides of each of the conductive pillars 106 and 108 are connected to different materials in different cross-sections. In some embodiments, each of the conductive pillars 106 and 108 is in contact with the dielectric material 98 in a first cross-section, while in contact with the ferroelectric layer 90, the channel layer 92 and the dielectric segments 99 in a second cross-section connected to the first cross-section, as shown in the right-bottom corner of FIG. 27A.

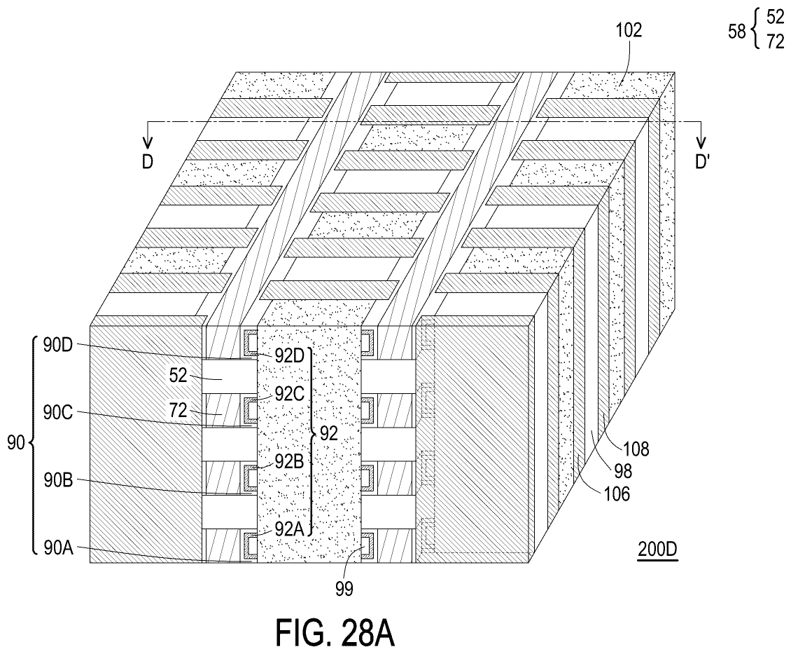

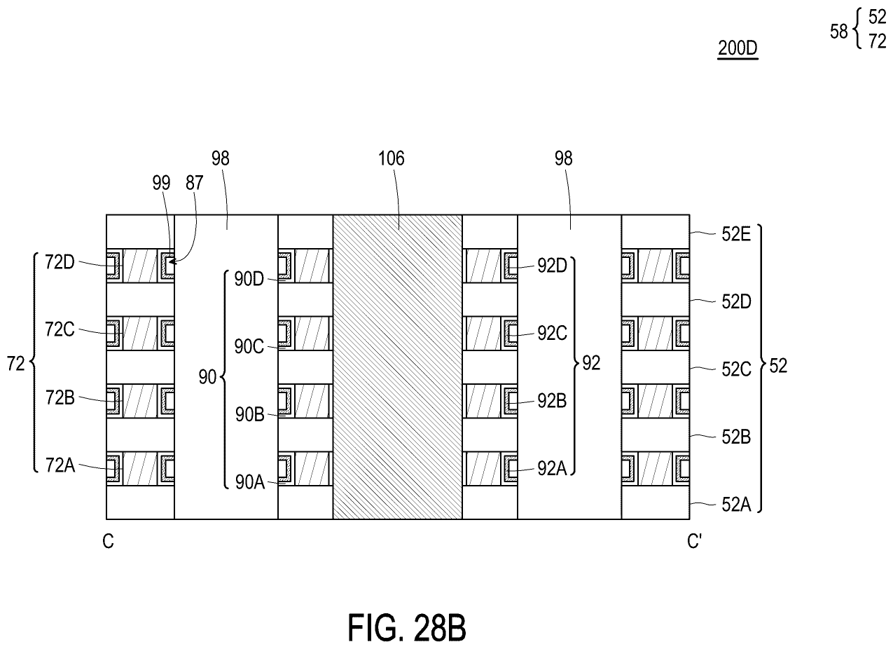

In the ferroelectric memory device 200C, the width of the conductive pillars 106 and 108 are substantially the same with the width of the isolation pillars 102. However, the disclosure is not limited thereto. In other embodiments, the width of the conductive pillars 106 and 108 may be greater than the width of the isolation pillars 102, as shown in the ferroelectric memory device 200D in FIG. 28A to FIG. 28B.

In some embodiments, each of the conductive pillars 106 and 108 is in contact with the ferroelectric layer 90 in a first cross-section, while in contact with the ferroelectric layer 90, the channel layer 92, the dielectric segments 99 and the dielectric material 98 in a second cross-section connected to the first cross-section, as shown in the right-bottom corner of FIG. 28A.

In the ferroelectric memory device 200A/200B/200C/200D, the channel segments 92A-92D each have a horizontal U-shape, and do not completely fill the recesses 87, respectively. However, the disclosure is not limited thereto. In other embodiments, the channel segments 92A-92D each have an I-shape, and completely fill the recesses 87, respectively.

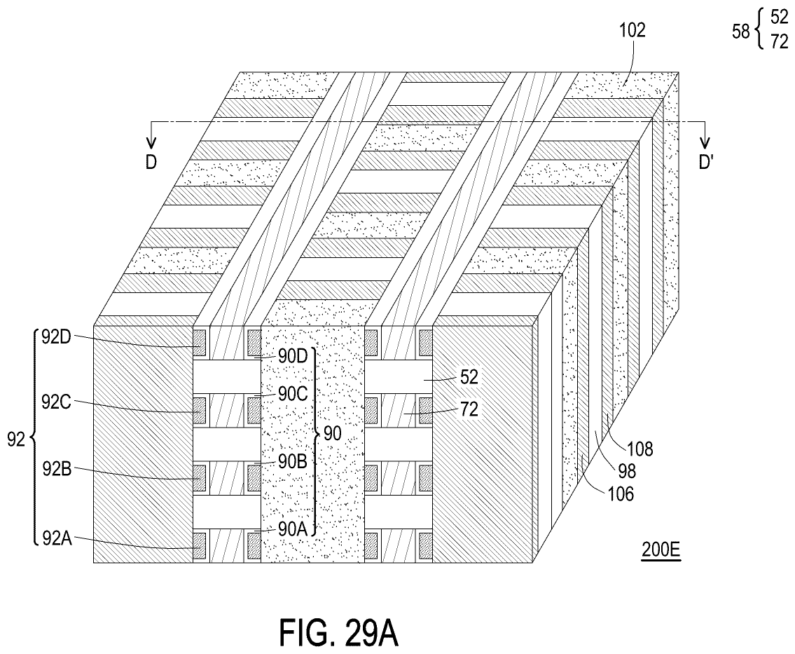

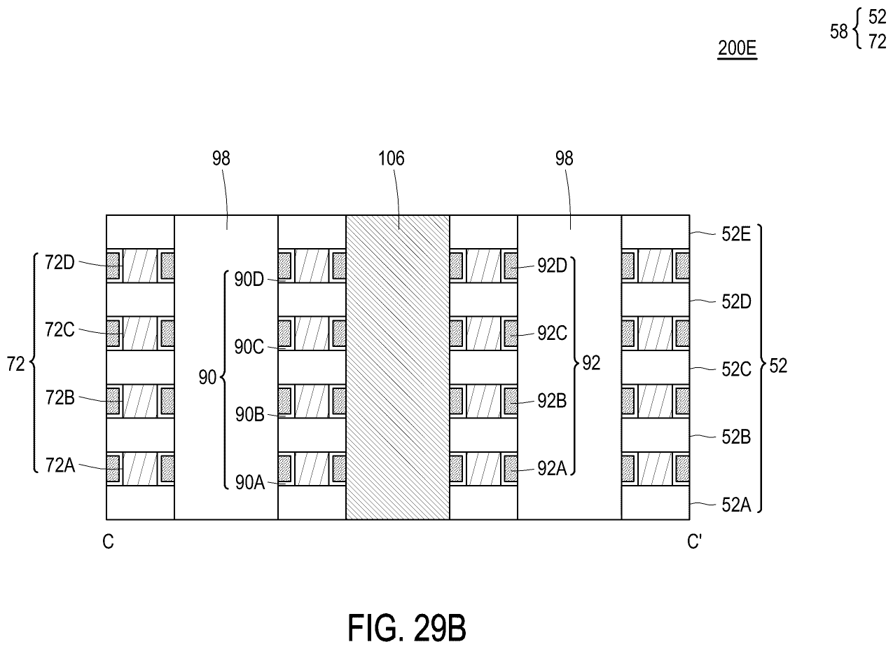

The method of forming the ferroelectric memory device 200E in FIG. 29A to FIG. 29B is similar to the method of forming the ferroelectric memory device 200C in FIG. 27A to FIG. 27B, so the difference between them is described below, and the similarity is not iterated herein. During the operation of FIG. 18A and FIG. 18B in forming a channel layer 91 on the ferroelectric layer 90, the channel layer 91 completely fills the recesses 87. Accordingly, the dielectric material 98 is merely formed in the trenches 86, without forming dielectric segments 99 in the recesses 87.

In some embodiments, two adjacent sides of each of the conductive pillars 106 and 108 are connected to different materials in different cross-sections. In some embodiments, each of the conductive pillars 106 and 108 is in contact with the dielectric material 98 in a first cross-section, while in contact with the ferroelectric layer 90 and the channel layer 92 in a second cross-section connected to the first cross-section, as shown in the right-bottom corner of FIG. 29A.

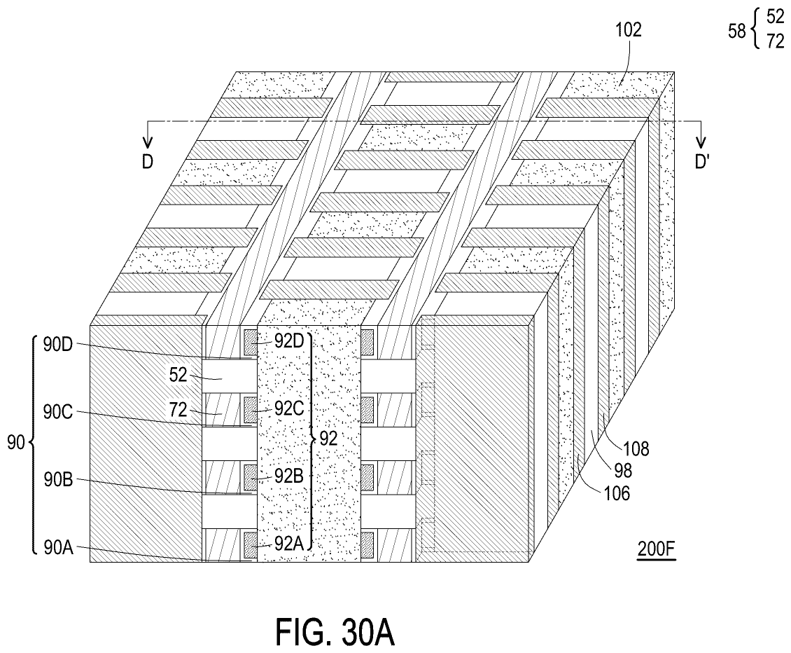

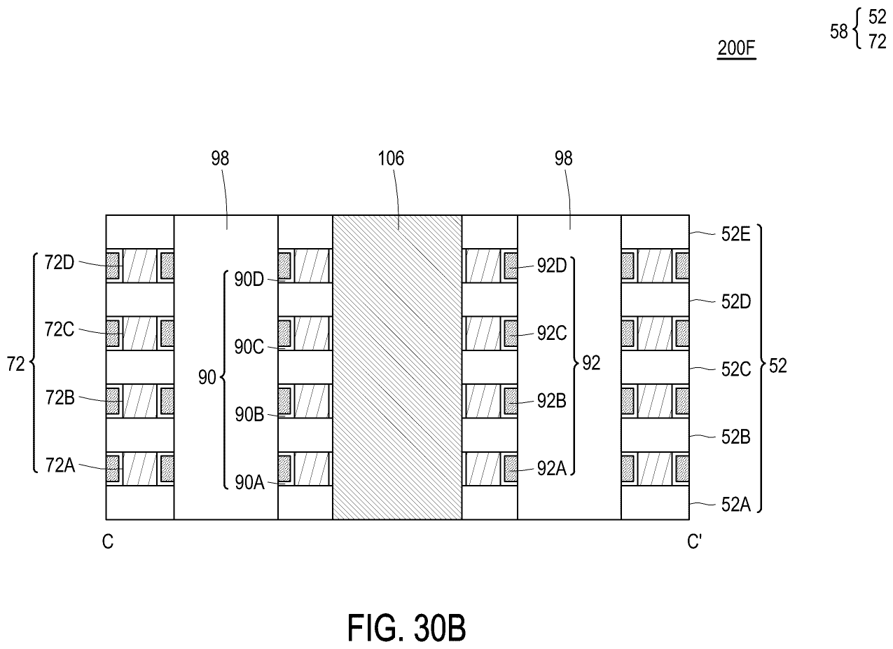

In the ferroelectric memory device 200E, the width of the conductive pillars 106 and 108 are substantially the same with the width of the isolation pillars 102. However, the disclosure is not limited thereto. In other embodiments, the width of the conductive pillars 106 and 108 may be greater than the width of the isolation pillars 102, as shown in the ferroelectric memory device 200F in FIG. 30A to FIG. 30B.

In some embodiments, each of the conductive pillars 106 and 108 is in contact with the ferroelectric layer 90 in a first cross-section, while in contact with the ferroelectric layer 90, the channel layer 92 and the dielectric material 98 in a second cross-section connected to the first cross-section, as shown in the right-bottom corner of FIG. 30A.

The structures of the ferroelectric memory devices of the disclosure are illustrated below with reference to FIG. 1A, FIG. 1B and FIG. 24A to FIG. 30B.

In accordance with some embodiments of the present disclosure, a ferroelectric memory device 200A/200B/200C/200D/200E/200F includes a multi-layer stack 58, a plurality of channel segments 92A-92D and a ferroelectric layer 90. The multi-layer stack 58 is disposed on a substrate 50 and includes a plurality of conductive layers 72A-72D and a plurality of dielectric layers 52A-52D stacked alternately. The channel segments 92A-92D are disposed on sidewalls of the conductive layers 72A-72D, separately and respectively. The ferroelectric layer 90 is disposed between the channel segments 92A-92D and the conductive layers 72A-72D, respectively.

In some embodiments, sidewalls of the conductive layers 72A-72D are recessed from sidewalls of the dielectric layers 52A-52D, such that one of the channel segments 92A-92D and a portion of the ferroelectric layer 90 are embedded in a space surrounded by one conductive layer 72 and two adjacent dielectric layers 52.

In some embodiments, the ferroelectric memory device 200A/200B/200C/200D further includes a plurality of dielectric segments 99 disposed aside the channel segments 92A-92D, respectively, wherein one dielectric segment 99 is embedded in the space surrounded by one conductive layer 72 and two adjacent dielectric layers 52.

In some embodiments, in the ferroelectric memory device 200A/200B, the ferroelectric layer 90 is a continuous layer along sidewalls of the conductive layers 72.

In some embodiments, in the ferroelectric memory device 200C/200D/200E/200F, the ferroelectric layer 90 is a discontinuous layer comprising a plurality of ferroelectric segments 90A-90D corresponding to the channel segments 92A-92D, respectively.

In some embodiments, in the ferroelectric memory device 200C/200D/200E/200F, each of the ferroelectric segments 90A-90D has a horizontal-U shape.

In some embodiments, in the ferroelectric memory device 200A/200B/200C/200D, each of the channel segments 92A-92D has a horizontal-U shape.

In some embodiments, in the ferroelectric memory device 200E/200F, each of the channel segments 92A-92D has an I-shape.

In accordance with alternative embodiments of the present disclosure, a ferroelectric memory device 200A/200B/200C/200D/200E/200F includes a multi-layer stack 58, at least one isolation pillar 102, a channel layer 92, a ferroelectric layer 90 and at least two conductive pillars 106 and 108. The multi-layer stack 58 is disposed on a substrate 50 and includes a plurality of conductive layers 72 and a plurality of dielectric layers 52 stacked alternately. The isolation pillar 102 is disposed on the substrate 50 and penetrates through the multi-layer stack 58. The channel layer 92 is disposed between the multi-layer stack 58 and the isolation pillar 102 and includes a plurality of channel segments 92A-92D corresponding to the conductive layers 72A-72D, respectively. The ferroelectric layer 90 is disposed between the channel layer 92 and the multi-layer stack 58. The at least two conductive pillars 106 and 108 are disposed on the substrate 50 and penetrate through the multi-layer stack 58, wherein the at least two conductive pillars 106 and 108 are disposed at two ends of the at least one isolation pillar 102. The ferroelectric layer 90 and the channel layer 92 are in contact with the conductive pillars 106 and 108.

In some embodiments, in the ferroelectric memory device 200A/200C/200E, a width of the conductive pillars 106 and 108 is substantially the same with a width of the isolation pillar 102.

In some embodiments, in the ferroelectric memory device 200B/200D/200F a width of the conductive pillars 106 and 108 is greater than a width of the isolation pillar 102.

Embodiments of the disclosure provide a ferroelectric memory device, in which a channel layer is cut into multiple channel segments corresponding to multiple gate electrodes. By such configuration, the cell-to-cell noise interference is prevented, the off current (I_{off}) or leaky current of the device is significantly reduced, and the Iₒₙ/I_{off} ratio is accordingly enhanced.

In the above embodiments, the ferroelectric memory device is formed by a “staircase first process” in which the staircase structure is formed before the memory cells are formed. However, the disclosure is not limited thereto. In other embodiments, the ferroelectric memory device may be formed by a “staircase last process” in which the staircase structure is formed after the memory cells are formed.

In the above embodiments, the gate electrodes (e.g., word lines) are formed by depositing sacrificial dielectric layers followed by replacing sacrificial dielectric layers with conductive layers. However, the disclosure is not limited thereto. In other embodiments, the gate electrodes (e.g., word lines) may be formed in the first stage without the replacement step as needed.

Many variations of the above examples are contemplated by the present disclosure. It is understood that different embodiments may have different advantages, and that no particular advantage is necessarily required of all embodiments.

In accordance with some embodiments of the present disclosure, a device includes a multi-layer stack, a plurality of channel segments and a ferroelectric layer. The multi-layer stack is disposed on a substrate and includes a plurality of conductive layers and a plurality of dielectric layers stacked alternately. The channel segments are disposed on sidewalls of the conductive layers, separately and respectively. The ferroelectric layer is disposed between the channel segments and the conductive layers, respectively.

In accordance with alternative embodiments of the present disclosure, a device includes a multi-layer stack, at least one isolation pillar, a channel layer, a ferroelectric layer and at least two conductive pillars. The multi-layer stack is disposed on a substrate and includes a plurality of conductive layers and a plurality of dielectric layers stacked alternately. The isolation pillar is disposed on the substrate and penetrates through the multi-layer stack. The channel layer is disposed between the multi-layer stack and the isolation pillar and includes a plurality of channel segments corresponding to the conductive layers, respectively. The ferroelectric layer is disposed between the channel layer and the multi-layer stack. The at least two conductive pillars are disposed on the substrate and penetrate through the multi-layer stack, wherein the at least two conductive pillars are disposed at two ends of the at least one isolation pillar. The ferroelectric layer and the channel layer are in contact with the conductive pillars.

In accordance with yet alternative embodiments of the present disclosure, a method of forming a device includes following operations. A multi-layer stack is formed on a substrate, wherein the multi-layer stack includes a plurality of dielectric layers and a plurality of conductive layers stacked alternately and has a trench penetrating therethrough. The conductive layers exposed by a sidewall of the trench are recessed, and therefore a plurality of recesses are formed. One of the plurality of recesses is formed between two adjacent dielectric layers. A ferroelectric layer is formed on the sidewall of the trench and fills in the recesses. A channel layer is formed on the ferroelectric layer and fills in the recesses.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a multi-layer stack, disposed on a substrate and comprising a plurality of conductive layers and a plurality of dielectric layers stacked alternately;
a plurality of channel segments, disposed on sidewalls of the plurality of conductive layers, separately and respectively; and
a ferroelectric layer, disposed between the plurality of channel segments and the plurality of conductive layers, respectively.

2. The device of claim 1, wherein the sidewalls of the plurality of conductive layers are recessed from sidewalls of the plurality of dielectric layers, such that one channel segment and a portion of the ferroelectric layer are embedded in a space surrounded by one conductive layer and two adjacent dielectric layers.

3. The device of claim 1, further comprising a plurality of dielectric segments disposed aside the channel segments, respectively, wherein one dielectric segment is embedded in a space surrounded by one conductive layer and two adjacent dielectric layers.

4. The device of claim 1 wherein the ferroelectric layer is a continuous layer along the sidewalls of the plurality of conductive layers.

5. The device of claim 1, wherein the ferroelectric layer is a discontinuous layer comprising a plurality of ferroelectric segments corresponding to the channel segments, respectively.

6. The device of claim 5, wherein each of the plurality of ferroelectric segments has a horizontal-U shape.

7. The device of claim 1, wherein each of the plurality of channel segments has a horizontal-U shape.

8. The device of claim 1, wherein each of the plurality of channel segments has an I-shape.

9. A device, comprising:
a multi-layer stack, disposed on a substrate and comprising a plurality of conductive layers and a plurality of dielectric layers stacked alternately;
at least one isolation pillar, disposed on the substrate and penetrating through the multi-layer stack;
a channel layer, disposed between the multi-layer stack and the isolation pillar and comprising a plurality of channel segments corresponding to the conductive layers, respectively;
a ferroelectric layer, disposed between the channel layer and the multi-layer stack; and
at least two conductive pillars disposed on the substrate and penetrating through the multi-layer stack, wherein the at least two conductive pillars are disposed at two ends of the at least one isolation pillar,
wherein the ferroelectric layer and the channel layer are in contact with the conductive pillars.

10. The device of claim 9, wherein sidewalls of the plurality of conductive layers are recessed from sidewalls of the plurality of dielectric layers, such that one channel segment and a portion of the ferroelectric layer are embedded in a space surrounded by one conductive layer and two adjacent dielectric layers.

11. The device of claim 9, further comprising a plurality of dielectric segments disposed aside the channel segments, respectively, wherein one dielectric segment is embedded in a space surrounded by one conductive layer and two adjacent dielectric layers.

12. The device of claim 9, wherein the ferroelectric layer is a continuous layer along sidewalls of the plurality of conductive layers.

13. The device of claim 9, wherein the ferroelectric layer is a discontinuous layer comprising a plurality of ferroelectric segments corresponding to the channel segments, respectively.

14. The device of claim 9, wherein a width of one of the conductive pillars is substantially the same with a width of the isolation pillar.

15. The device of claim 9, wherein a width of one of the conductive pillars is greater than a width of the isolation pillar.

16. A method of forming a device, comprising:
forming a multi-layer stack on a substrate, wherein the multi-layer stack comprises a plurality of dielectric layers and a plurality of conductive layers stacked alternately and has a trench penetrating therethrough;
recessing the plurality of conductive layers exposed by a sidewall of the trench and therefore forming a plurality of recesses, wherein one of the plurality of recesses is formed between two adjacent dielectric layers;
forming a ferroelectric layer on the sidewall of the trench and filling in the recesses; and
forming a channel layer on the ferroelectric layer and filling in the recesses.

17. The method of claim 16, further comprising performing an etching back process to remove the channel layer outside of the recesses.

18. The method of claim 17, wherein the etching back process further removes the ferroelectric layer outside of the recesses.

19. The method of claim 16, further comprising forming a dielectric material on the channel layer and filling in the recesses.

20. The method of claim 16, wherein the channel layer completely fills the recesses.
